(19) United States
(12) Patent Application Publication
(10) Pub. No.: US 2025/0349538 A1
(43) Pub. Date: Nov. 13, 2025

(54) MEGASONICALLY EXFOLIATED TWO-DIMENSIONAL NANOMATERIAL INKS, FABRICATING METHODS, AND APPLICATIONS OF THE SAME

(71) Applicant: NORTHWESTERN UNIVERSITY, Evanston, IL (US)

(72) Inventors: Mark C. Hersam, Wilmette, IL (US); Lidia Kuo, Evanston, IL (US); Sonal V. Rangnekar, Chicago, IL (US); Vinod K. Sangwan, Evanston, IL (US)

(21) Appl. No.: 18/871,212

(22) PCT Filed: May 18, 2023
(86) PCT No.: PCT/US2023/022664

§ 371 Date: Dec. 3, 2024

Related U.S. Application Data
(60) Provisional application No. 63/349,179, filed on Jun. 6, 2022.

(51) Int. Cl. H01L 21/02; C09D 11/033; C09D 11/037; C09D 11/38; C09D 11/52

(52) U.S. Cl. CPC H01L 21/02601; C09D 11/033; C09D 11/037; C09D 11/38; C09D 11/52; H01L 21/02565; H01L 21/02568; H01L 21/02628

(57) ABSTRACT

The invention discloses a megasonically exfoliated two-dimensional (2D) nanomaterial ink. The megasonically exfoliated 2D nanomaterial ink is then aerosol-jet printed (AJP) onto printed graphene electrodes to achieve all-AJP, flexible photodetectors. The 2D nanomaterial AJP ink is designed with terpineol, a high boiling point solvent, which enables a highly ordered thin-film morphology and also improves the photogenerated charge transport. After printing, the photodetectors are photonically annealed, which provides quasi-ohmic contacts and photoactive channels with responsivities that outperform previously reported all-printed visible photodetectors by over 3 orders of magnitude. Megasonic exfoliation coupled with AJP allows the superlative optoelectronic properties of ultrathin nanosheets to be utilized in the scalable additive manufacturing of mechanically flexible optoelectronics.

### CROSS-REFERENCE TO RELATED PATENT APPLICATION

This application claims priority to and the benefit of U.S. Provisional Patent Application No. 63/349,179, filed Jun. 6, 2022, which is incorporated herein in its entirety by reference.

### STATEMENT AS TO RIGHTS UNDER FEDERALLY-SPONSORED RESEARCH

This invention was made with government support under grant number 70NANB19H005 awarded by the National Institute of Standards and Technology and grant numbers 2037026, DGE1842165, DMR1720139 awarded by the National Science Foundation. The government has certain rights in the invention.

### FIELD OF THE INVENTION

The present invention generally relates to material science, particularly to megasonically exfoliated two-dimensional nanomaterial inks, fabricating methods, and applications of the same.

### BACKGROUND OF THE INVENTION

The background description provided herein is to present the context of the invention generally. The subject matter discussed in the background of the invention section should not be assumed to be prior art merely due to its mention in the background of the invention section. Similarly, a problem mentioned in the background of the invention section or associated with the subject matter of the background of the invention section should not be assumed to have been previously recognized in the prior art. The subject matter in the background of the invention section merely represents different approaches, which in and of themselves may also be inventions. Work of the presently named inventors, to the extent it is described in the background of the invention section, as well as aspects of the description that may not otherwise qualify as prior art at the time of filing, are neither expressly nor impliedly admitted as prior art against the invention.

Due to their unique optoelectronic properties, two-dimensional (2D) materials are promising candidates for tunable, high-performance optoelectronic devices that are vital for optical detection and quantum communication. To achieve scalable production of 2D nanosheets, liquid-phase exfoliation (LPE) has been widely explored but frequently yields compromised electronic properties compared to micromechanical exfoliation. In LPE, bulk crystals are exfoliated into few-layer nanosheets, often using ultrasonic energy in the presence of an appropriate solvent and/or stabilizer, followed by size selection via centrifugation. While individual LPE nanosheets may exhibit high optoelectronic quality, devices based on percolating nanosheet films typically suffer from large contact resistance between nanosheets. One strategy for lowering intersheet resistance is the optimization of LPE processes to obtain high aspect ratio nanosheets with large lateral sizes, thus decreasing the number of intersheet junctions and increasing the conductivity of the percolating path. Although high aspect ratio, electronic-grade nanosheets have been obtained using electrochemical intercalation prior to LPE, there has been limited integration of these intercalation-derived 2D materials into printed optoelectronics, likely due to challenges in achieving well-aligned and flat percolating networks following printing and subsequent solvent evaporation. The resulting disordered percolating network morphology for printed LPE nanoflakes leads to inferior optoelectronic performance compared to chemical vapor deposition (CVD) grown or mechanically exfoliated counterparts.

In addition, 2D) materials have layer-dependent properties that allow tunable optical and electronic properties as a function of thickness. In particular, high aspect ratio monolayer nanosheets are ideal for achieving high-performance optoelectronic devices. Solution-processing is a cost-effective and scalable method to exfoliate 2D materials with varying thickness and size, which then can be formulated into printable electronic inks. However, solution-exfoliated nanosheets suffer from thickness and aspect ratio polydispersity, thus necessitating low-yield centrifugal separation to isolate the thinnest, highest aspect ratio materials.

Therefore, a heretofore unaddressed need exists in the art to address the aforementioned deficiencies and inadequacies.

### SUMMARY OF THE INVENTION

In view of the aforementioned deficiencies and inadequacies, this invention discloses a novel technique to increase the fraction of large-area (i.e., micron-sized) monolayer nanosheets from electrochemically exfoliated MoS₂, by using sonication at megahertz frequencies (i.e., megasonic exfoliation). The resulting megasonically exfoliated MoS₂ ink is then aerosol-jet printed (AJP) onto printed graphene electrodes to achieve all-AJP, flexible photodetectors. The MoS₂ AJP ink is designed with terpineol, a high boiling point solvent, which enables a highly ordered thin-film morphology, which also improves the photogenerated charge transport. After printing, the photodetectors are photonically annealed, which provides quasi-ohmic contacts and photoactive channels with responsivities that outperform previously reported all-printed visible photodetectors by over 3 orders of magnitude. Megasonic exfoliation coupled with AJP allows the superlative optoelectronic properties of ultrathin MoS₂ nanosheets to be utilized in the scalable additive manufacturing of mechanically flexible optoelectronics.

Specifically, in one aspect, the invention relates to a nanomaterial ink, comprising at least one solvent; and at least one two-dimensional (2D) semiconductor dispersed in the at least one solvent.

In one embodiment, the nanomaterial ink further comprises at least one ink additive that affects at least one ink property including substrate wetting, rheology, particle aggregation, particle stability, phase stability, UV stability, fluorescence, ink drying dynamics, electrical properties, pH stability, foaming, and oxidation.

In one embodiment, the at least one ink additive comprises surfactants including sodium cholate, sodium dodecylsulfate, and/or cetyl trimethylammonium bromide; or polymers including polyvinylpyrrolidone, ethyl cellulose, nitrocellulose, nanocellulose, and/or poloxamers.

In one embodiment, the at least one solvent comprises water; low boiling point alcohols including ethanol, isopropyl alcohol, and/or 2-butanol; polar aprotic solvents including acetone, acetonitrile, N-methyl pyrrolidone, dimethylformamide, N-cyclohexyl-2-pyrrolidone, propylene carbonate, dimethyl sulfoxide, tetrahydrofuran, and/or dihydrolevoglucosenone; high boiling point organic solvents including ethylene glycol, terpineol, and/or dibutyl phthalate; and/or other organic solvents including toluene, xylene, ethyl lactate, and/or cyclohexanone.

In one embodiment, the at least one 2D semiconductor comprises nanoparticles comprising nanosheets, nanoflakes, nanofibers, nanotubes, or combinations of them.

In one embodiment, the at least one 2D semiconductor comprises elemental semiconductors including phosphorene, germanene, tellurine, selenine, and/or stanine; monochalcogenides including GeS, InSe, GaTe, PbTe, SnS, and/or SnSe; dichalcogenides including MoS₂, WSe₂, TaS₂, ReS₂, and/or MoTe₂; trichalcogenides including NbSe₃, GaInS₃, Bi₂Se₃, and/or In₂Se₃; 2D semiconducting oxides such as MnO₃ and/or V₂O₅; and/or semiconducting MXenes including Mn₂CO₂, Ti₂C, Sc₂CF₂, and/or Cr₂CF₂.

In one embodiment, the at least one 2D semiconductor is obtained by electrochemical intercalation, and exfoliation in liquid.

In one embodiment, the exfoliation process comprises megasonic exfoliation.

The nanomaterial ink of claim 6, wherein the at least one 2D semiconductor has thicknesses at a single-nanometer scale and lateral sizes at a micron-scale.

In one embodiment, the at least one 2D semiconductor has the thicknesses of less than about 2 nm, and the lateral sizes of about 0.5-3 μm.

In one embodiment, the nanomaterial ink is applicable for drop casting, spin coating, dip coating, spray coating, blade coating, inkjet printing, aerosol jet printing, gravure printing, screen printing, electrodynamic jet printing, direct ink writing, 3D printing, microcontact printing, Langmuir-Blodgett assembly, layer-by-layer assembly, field-directed assembly, vacuum filtration assembly, and confined assembly.

In one embodiment, the nanomaterial ink is formed such that a film is formable to have percolating networks by a single printing pass, or multiple printing passes of the 2D nanomaterial ink.

In another aspect, the invention relates to a method of forming a nanomaterial ink, comprising providing at least one 2D semiconductor; and dispersing the at least one 2D semiconductor in at least one solvent to form the nanomaterial ink.

In one embodiment, the at least one solvent comprises water; low boiling point alcohols including ethanol, isopropyl alcohol, and/or 2-butanol; polar aprotic solvents including acetone, acetonitrile, N-methyl pyrrolidone, dimethylformamide, N-cyclohexyl-2-pyrrolidone, propylene carbonate, dimethyl sulfoxide, tetrahydrofuran, and/or dihydrolevoglucosenone; high boiling point organic solvents including ethylene glycol, terpineol, and/or dibutyl phthalate; and/or other organic solvents including toluene, xylene, ethyl lactate, and/or cyclohexanone.

In one embodiment, said providing the at least one 2D semiconductor comprises electrochemically intercalating crystalline domains of a layered semiconductor material to obtain an intercalated crystal or powder; and pre-exfoliating the intercalated crystal semiconductor using bath sonication to obtain the at least one 2D semiconductor.

In one embodiment, the at least one 2D semiconductor comprises nanoparticles comprising nanosheets, nanoflakes, nanofibers, nanotubes, or combinations of them.

In one embodiment, the at least one 2D semiconductor comprises elemental semiconductors including black phosphorus, germanene, tellurine, and selenine; monochalcogenides including GeS, InSe, GaTe, PbTe, SnS, and SnSe; dichalcogenides including MoS₂, WSe₂, TaS₂, ReS₂, MoTe₂; trichalcogenides including NbSe₃, GaInS₃, Bi₂Se₃, and In₂Se₃; 2D semiconducting oxides such as MnO₃ and V₂O₅; and semiconducting MXenes including Mn₂CO₂, Ti₂C, Sc₂CF₂, and Cr₂CF₂.

In one embodiment, the method further comprises megasonically exfoliating the nanomaterial ink.

In one embodiment, the at least one 2D semiconductor has thicknesses at a single-nanometer scale and lateral sizes at a micron-scale.

In one embodiment, the at least one 2D semiconductor has the thicknesses of less than about 2 nm, and the lateral sizes of about 0.5-3 μm.

In one embodiment, said megasonic exfoliation of the nanomaterial ink is performed in a container containing one or several piezoelectric transducers.

In one embodiment, said megasonic exfoliation of the nanomaterial ink is performed in a container containing a single piezoelectric transducer with a resonant frequency larger than 350 kHz, such as but not limited to 950 kHz or 1.65 MHz.

In one embodiment, said megasonic exfoliation of the nanomaterial ink is performed in a container containing an array of piezoelectric transducers, each with an independent resonant frequency larger than 350 kHz, such as but not limited to 950 kHz or 1.65 MHz.

In one embodiment, said megasonic exfoliation of the nanomaterial ink is performed in a container containing one or several piezoelectric transducers, and the ink is placed directly into the container for exposure to the megasonic acoustic energy.

In one embodiment, said megasonic exfoliation of the nanomaterial ink is performed in a container containing one or several piezoelectric transducers and an acoustic medium including water.

In one embodiment, said megasonic exfoliation of the nanomaterial ink is performed in a container containing one or several piezoelectric transducers and an acoustic medium including water, in which the nanomaterial ink is placed in a secondary container that is submerged in the acoustic medium and is designed to transmit megasonic frequency.

In one embodiment, said megasonic exfoliation of the nanomaterial ink is performed in a megasonic container including one or several piezoelectric transducers and an acoustic medium including water, in which the nanomaterial ink is placed in a thin-walled plastic container that is held at the surface of the acoustic medium or is submerged in the acoustic medium.

In one embodiment, said megasonic exfoliation of the nanomaterial ink is performed in a megasonic container including one or several piezoelectric transducers and an acoustic medium including water, in which the nanomaterial ink is placed in a thin-walled plastic container that may or may not be permeable to air.

In one embodiment, said megasonic exfoliation of the nanomaterial ink is performed using an aerosol jet printer (AJP) outfitted with an ultrasonic atomizer that operates at a frequency greater than 350 kHz, such as 1.65 MHz.

In yet another aspect, the invention relates to an electronic device or an optoelectronic device, either comprising at least one element formed of the nanomaterial ink on a substrate.

In one embodiment, the substrate comprises a rigid substrate or a flexible substrate.

In one embodiment, the at least one element is thermally annealed or photonically annealed.

In one embodiment, the optoelectronic device further comprises electrodes coupled with the at least one element.

In one embodiment, the electrodes are formed by gas phase deposition of a metal or a stack of metals including gold, chromium, indium, nickel, and titanium.

In one embodiment, the electrodes are formed by growth of a conductive material including graphene, MoO₃, and NbS₂.

In one embodiment, the electrodes are formed by depositing a conductive ink comprising at least one active material including metal nanoparticles or metal complexes including gold, silver, copper, nickel, palladium, and/or platinum; liquid metals including eGaIn; carbon nanomaterials including carbon nanotubes, graphene, fullerenes, graphene oxide, and/or reduced graphene oxide; conductive polymers including poly(3,4-ethylenedioxythiophene) polystyrene sulfonate (PEDOT:PSS), polyaniline (PANI), polypyrrole (PPy), polyacetylene, and/or polythiophene (PT); and conductive 2D materials including 1T-MoS₂, NbS2, and/or Ti3C2Tx MXenes. In one embodiment, the electronic device is a transistor, a memristor, a diode, a power converter, a sensor, a battery, a resistor, integrated circuit elements, or combinations of them.

In one embodiment, the optoelectronic device is a photodetector, a photosensor, a photodiode, a solar cell, a phototransistor, a light-emitting diode, a laser diode, integrated optical circuit (IOC) elements, a photoresistor, a charge-coupled imaging device, or combinations of them.

In one embodiment, the at least one element is formed by aerosol jet printing (AJP), during which megasonic atomization induces exfoliation and yields a high fraction of monolayer nanosheets of the at least one 2D semiconductor.

In one embodiment, the optoelectronic device has responsivities exceeding 10³ A/W that outperforms previously reported all-printed visible photodetectors by over 3 orders of magnitude.

In one aspect, the invention relates to a method of forming an optoelectronic device, comprising forming at least one element on a substrate with the nanomaterial ink; and annealing the at least one element to decompose the solvent and enhance electrical contact between nanoparticles of the at least one 2D semiconductor in the at least one element.

In one embodiment, the method further comprises forming electrodes with a graphene ink, wherein the electrodes are coupled with the at least one element.

In one embodiment, said forming the at least one element is performed with aerosol jet printing (AJP), during which megasonic atomization induces exfoliation and yields a high fraction of monolayer nanosheets of the at least one 2D semiconductor.

In one embodiment, said annealing the at least one element is performed with thermal annealing or photonic annealing.

These and other aspects of the present invention will become apparent from the following description of the preferred embodiment taken in conjunction with the following drawings, although variations and modifications therein may be affected without departing from the spirit and scope of the novel concepts of the invention.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment.

FIG. 1 shows megasonic exfoliation (MSE) characterization according to embodiments of the invention. Panel a: Schematic diagram of aerosol jet printing (AJP), depicting aerosolization via megasonic atomization. Panel b: Optical absorbance spectra of the MoS₂ inks following different MSE times. The inset shows the color comparison of the MoS₂ inks (left) before and (right) after MSE. Panel c: Raman spectra before and after MSE. Panel d: Photoluminescence spectra before and after MSE. Panel e: Atomic force microscopy (AFM)-derived flake thickness histograms before and after MSE. Panel f: AFM-derived flake lateral size histogram before and after MSE.

FIG. 2 shows printing characterization according to embodiments of the invention. Panel a: Schematic showing AJP deposition and printed photodetector geometry. Panel b: Grazing incidence wide angle X-ray scattering (GIWAXS) map of a printed MoS₂ film, showing uniaxial texture along the c-axis to confirm flat, stacked flakes. Panel c: Atomic force microscopy (AFM) topography image of MoS₂ deposited by AJP when terpineol is included in the ink formulation, showing flat MoS₂ flakes. Panel d: AFM topography image of MoS₂ deposited by AJP without terpineol included in the ink formulation, showing crumpled MoS₂ flakes; note the 20-fold-wider height range.

FIG. 3 shows photocurrent and charge transport characterization according to embodiments of the invention. Panel a: Optical microscope image of a photonically annealed (PA) device. The area used for scanning photocurrent microscopy (SPCM) mapping is shown in the blue square. Panel b: The corresponding spatially resolved SPCM map of the scanned area, measured at an applied bias of 4 V with a 630 nm laser at a power of 41 μW. A 1.5 μm laser spot size was used. Panel c: Corresponding averaged horizontal line profile of photocurrent and relative integrated graphene (Gr) Raman intensity for the SPCM image. Panel d: Current-voltage (I-V) characteristics under dark conditions of the PA device, revealing linear behavior for all temperatures when the applied bias exceeds 0.1 V.

FIG. 4 shows all-printed photodetector performance according to embodiments of the invention. Panel a: Photocurrent spectral response, normalized by wavelength. Panel b: Responsivity as a function of the number of printing passes, taken at an applied bias of 40 V, using a 515.6 nm laser with an intensity of 6.9×10⁻⁵ W/cm². All error bars indicate one standard deviation from the mean. Panel c: Responsivity as a function of illumination power measured for samples with 5 printing passes at 40 V with a 515.6 nm laser. Panel d: Bending stability over 10³ cycles with a bending radius of 12 mm. Responsivities were extracted from current-voltage curves at 40 V, using a 515.6 nm laser with a 5.67×10⁻² W/cm² intensity. A 3-print pass PA device and a 12-print pass thermally annealed (TA) device were measured. Panel e: Time-dependent photocurrent at an applied bias of 20 V and otherwise identical measurement conditions as panel d. Panel f: Responsivity and response time comparison to previously reported all-printed visible photodetectors. References are detailed in Table 2.

FIG. 5 shows electrochemical intercalation apparatus according to embodiments of the invention. Panel a: Schematic of the tetraheptylammonium bromide (THAB) intercalation apparatus, where the platinum foil serves as the counter electrode and the to-be-intercalated crystal (e.g., MoS₂) acts as the working electrode. The THAB in acetonitrile is clear at the start of the reaction, when a negative bias is applied to the working electrode. Panel b: At the end of the reaction, an evident color change is observable, indicating the formation of Br₂ at the counter electrode. Meanwhile, the MoS₂ crystal is expanded, indicating successful intercalation.

FIG. 6 shows extended printing formulation characterization according to embodiments of the invention. Panels a-b: Optical micrographs of aerosol-jet-printed (AJP) lines of MoS₂ formulated with and without terpineol, respectively, on SiO₂. The darker contrast of the film without terpineol in panel b indicates scattering from thicker, crumpled flakes. Panels c-d: Scanning electron microscopy (SEM) images of the printed MoS₂ ink with and without terpineol, respectively. Significant overspray is observed without terpineol. SEM images were obtained on a Hitachi 8030 SEM at an accelerating voltage of 2 kV. Panels e-f: Zoomed-in SEM images of the printed ink with and without terpineol, respectively.

FIG. 7 shows printed flake characterization according to embodiments of the invention. Panel a: Atomic force microscopy (AFM) scan of a single printed flake with the corresponding height profile of the white line. Panel b: Transmission electron microscopy (TEM) image of a single MoS₂ flake after megasonic exfoliation (MSE). Images were collected with a JEOL ARM300F GrandARM TEM with an accelerating voltage of 300 kV. Panel c: Lattice-resolved high-resolution TEM (HRTEM) image of the corresponding MoS₂ flake. Panel d: Selected area electron diffraction (SAED) of the MoS₂ flake. HRTEM and SAED confirm that MoS₂ crystallinity is preserved after MSE. Samples for HRTEM and SAED were prepared by pipetting 10 to 20 drops of MoS₂ solution onto a 400 mesh TEM copper grid with a lacey carbon support (Ted-Pella) and allowing the grid to dry completely on filter paper before being placed in a vacuum chamber overnight.

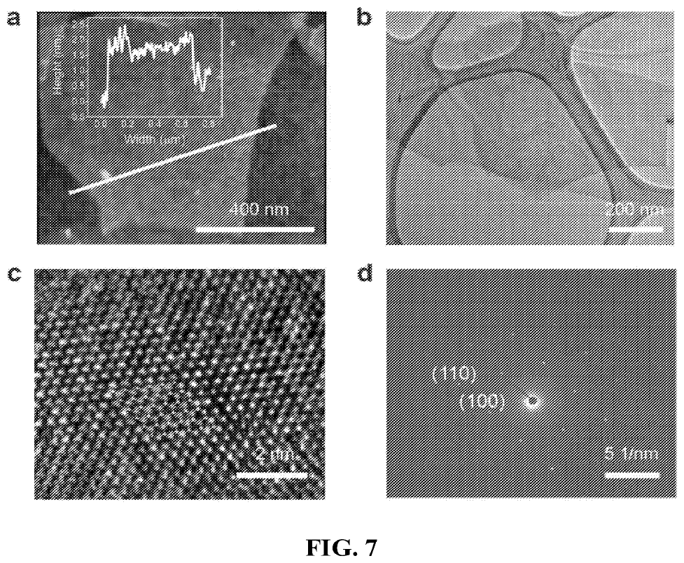

FIG. 8 shows post-processing X-Ray photoelectron spectroscopy (XPS) characterization according to embodiments of the invention. Panel a: Mo 3d XPS scans of the photonically annealed (PA) and thermally annealed (TA) films. Panel b: S 2p XPS scans of the PA and TA films. Characteristic MoS₂ XPS peaks (Mo 3d_{5/2}≈229.5 eV, Mo 3d_{3/2}≈232.5 eV, S 2p_{3/2}≈162.5 eV, S 2p_{1/2}≈163.7 eV) are present for both films. The two films have similar S:Mo atomic ratios of about 1.9, indicating the presence of sulfur vacancies. A small degree of oxidation is observed in the printed films, as both types of films exhibited peaks at 235.6 eV, characteristic of MoOₓ, and 168.5 eV, indicative of oxysulfides, resulting in atomic percentages of MoOₓ-related Mo peaks of 7.6% and 6.2% for the PA and TA films, respectively.

FIG. 9 shows post-processing optical and AFM characterization according to embodiments of the invention. Panels a-b: Optical microscopy images of the PA device and TA device, respectively. The PA device in panel a is more optically opaque due to increased light scattering resulting from its more disordered film morphology. Graphene (Gr) contacts and the MoS₂ channel are labeled. Panel c-d: AFM amplitude scans at the channel and contact interfaces of the PA and TA devices, respectively.

FIG. 10 shows extended post-processing characterization according to embodiments of the invention. Panel a: Grazing incidence wide-angle X-ray scattering (GIWAXS) from the polyimide substrate. The polyimide substrate strongly scatters. Panels b-c: GIWAXS of a photonically annealed film and thermally annealed film, respectively. Data has been corrected (imperfectly) for substrate scattering. Horizontal banding in panel b and panel c is an artifact of the polyimide background subtraction. Diffraction reveals no significant differences in c-axis orientation between the two processing methods. Panels d-e: SEM of a photonically annealed and thermally annealed film, respectively, confirming similar morphology in the c-direction in the two films. The only notable difference is that the thermally annealed film is smoother, requiring a tilted angle to observe the film cross-sectionally in panel e.

FIG. 11 shows C-axis coherence and orientation according to embodiments of the invention. Panel a: Radial sector average (+/−8°) through the (103) peak. Panel b: Tangential average (+/−0.2 Å−1) through the (103) peak. No significant change is observed in either the orientation distribution or the c-axis coherence between the thermally annealed and the photonically annealed samples.

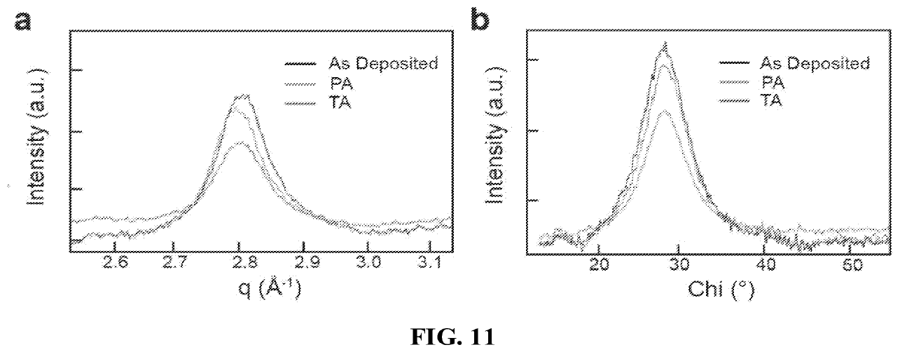

FIG. 12 shows scanning photocurrent microscopy (SPCM) and charge transport characterization according to embodiments of the invention. Panel a: Optical microscopy image of a TA device. The SPCM scanned area is shown in the blue square. Panel b: The corresponding SPCM image of scanned area. Panel c: Corresponding averaged horizontal line profile of the photocurrent and relative graphene Raman intensity in the SPCM image. Panel d: Current-voltage curves under dark conditions of the TA device, revealing non-ohmic behavior at all biases below 55 K.

FIG. 13 shows graphene Raman mapping supporting SPCM analysis according to embodiments of the invention. Panel a: Optical image of a printed MoS₂ photodetector, showing zoomed-in channel and contact regions. Panel b: Raman plots at various points of the device. Panel c: Zoomed-in Raman plot at the graphene contact, showing characteristic D and G bands. Panel d: Zoomed-in Raman plot at the graphene edge, where the D and G bands are less intense. Panel e: Zoomed-in Raman plot away from the graphene edge, showing large background intensity from the polyimide substrate. To correlate the SPCM data to the graphene contacts and MoS₂ channel, Raman mapping was performed of the scanned area using the characteristic D and G graphene peaks (FIG. 11). We chose to scan for graphene peaks rather than MoS₂ peaks due to the high background signal from the polyimide substrate. We can estimate the graphene thickness from the measured intensity:

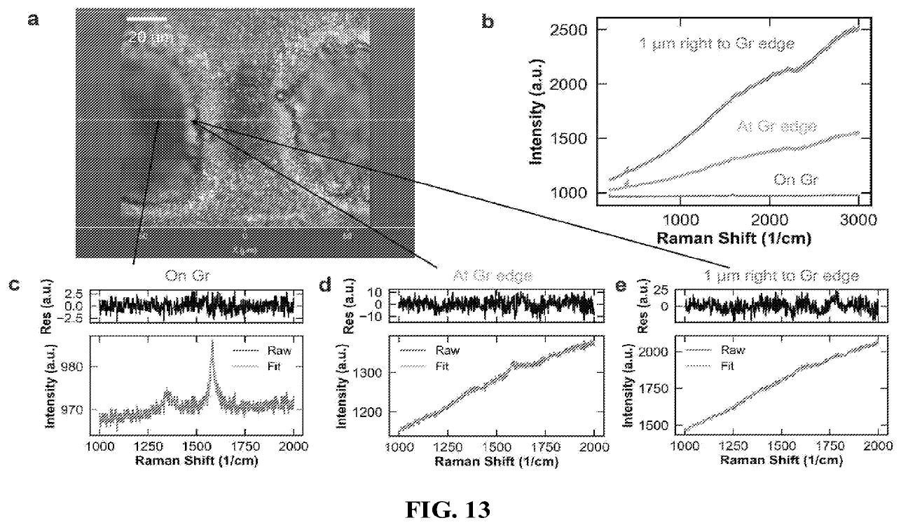

$$α t = log ( \frac{{I}_{0}}{{I}_{T}} ) and \frac{{I}_{0}}{{I}_{T}} \approx \frac{{I}_{ma x}}{I ( x )} , so t ∝ log ( \frac{{I}_{ma x}}{I ( x )} ) ,$$

where t is thickness, and I is intensity. The relative intensity was calculated by integrating between 2000 cm⁻¹ and 3000 cm⁻¹ after removing the background signal from the polyimide substrate.

FIG. 14 shows noise spectral density according to embodiments of the invention. Panel a: Noise spectral density (SI) as a function of frequency (f) at various applied voltages for a PA device. Panel b: SI at f=1 Hz shows approximately S_{I}˜I² behavior, suggesting that the measurements do not contribute to the measured noise. We measured noise spectral density, SI, to calculate detectivity, D* (FIG. 14). Our measurements were performed on a five-pass printed, photonically annealed device under dark conditions. We determine S_{I} as 7.4×10−9 A/Hz^{1/2} at 40 V and a frequency of 1 Hz.

FIG. 15 shows AJP versus drop-casted photodetectors according to embodiments of the invention. Panel a: Responsivity as a function of dark current for AJP and drop-casted photodetectors measured at 40 V at 515.6 nm with a laser power of 6.94×10⁻⁵ W/cm². Panel b: Current-voltage curves reveal more photocurrent produced for AJP films than dropcasted films for devices with similar dark currents, thus highlighting the improved performance for the direct bandgap, megasonically-thinned MoS₂ nanosheets. To evaluate the effects of megasonic exfoliation, the MoS₂ ink was drop-casted onto 50 μm×50 μm printed graphene bottom electrodes on polyimide. The hotplate was set to 80° C. while drop-casting. When dried, the photodetector was then processed by photonic annealing at 2.8 kV for 1.36 ms, or the same conditions as the printed photodetectors. Dark currents produced by the photodetectors were used as a proxy for comparing films of similar thicknesses.

FIG. 16 shows temperature dependence comparison according to embodiments of the invention. Panel a: Dark current as a function of temperature for PA and TA films. Dark currents generally increased with higher temperatures for both the TA and PA films, although the TA device had greater temperature sensitivity, resulting in a linear trend with a greater positive slope. Error bars indicate one standard deviation from the mean. Panel b: Photocurrent as a function of temperature, showing that the TA films exhibit greater temperature dependence. Greater temperature dependence in the TA films suggests that TA results in greater photothermal effects arising from a comparatively increased degree of trap states, in agreement with the power dependence and time response data.

### DETAILED DESCRIPTION OF THE INVENTION

The invention will now be described more fully hereinafter with reference to the accompanying drawings, in which exemplary embodiments of the invention are shown. However, this invention may be embodied in many different forms and should not be construed as limited to the embodiments set forth herein. Rather, these embodiments are provided so that this specification will be thorough and complete and fully convey the invention's scope to those skilled in the art. Like reference numerals refer to like elements throughout.

The terms used in this specification generally have their ordinary meanings in the art, within the context of the invention, and in the specific context where each term is used. Certain terms used to describe the invention are discussed below, or elsewhere in the specification, to provide additional guidance to the practitioner regarding the description. For convenience, certain terms may be highlighted, for example using italics and/or quotation marks. The use of highlighting has no influence on the scope and meaning of a term; the scope and meaning of a term are the same, in the same context, whether or not it is highlighted. It will be appreciated that same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and in no way limits the scope and meaning of the invention or of any exemplified term. Likewise, the invention is not limited to various embodiments given in this specification.

It will be understood that, as used in the description herein and throughout the claims that follow, the meaning of “a”, “an”, and “the” includes plural reference unless the context clearly dictates otherwise. Also, it will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, or section without departing from the invention's teachings.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures. is turned over, elements described as being on the “lower” side of other elements would then be oriented on “upper” sides of the other elements. The exemplary term “lower”, can, therefore, encompasses both an orientation of “lower” and “upper,” depending on the particular orientation of the figure. Similarly, if the device in one of the figures is turned over, elements described as “below” or “beneath” other elements would then be oriented “above” the other elements. Therefore, the exemplary terms “below” or “beneath” can encompass both an orientation of above and below.

It will be further understood that the terms “comprises” and/or “comprising,” or “includes” and/or “including” or “has” and/or “having”, or “carry” and/or “carrying,” or “contain” and/or “containing,” or “involve” and/or “involving, and the like are to be open-ended, i.e., to mean including but not limited to. When used in this specification, they specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification, and will not be interpreted in an idealized or overly formal sense unless expressly so defined herein.

As used in this specification, “around”, “about”, “approximately” or “substantially” shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated.

As used in this specification, the phrase “at least one of A, B, and C” should be construed to mean a logical (A or B or C), using a non-exclusive logical OR. As used herein, the term “and/or” includes any and all combinations of one or more of the associated listed items.

The description below is merely illustrative in nature and is in no way intended to limit the invention, its application, or uses. The broad teachings of the invention can be implemented in a variety of forms. Therefore, while this invention includes particular examples, the true scope of the invention should not be so limited since other modifications will become apparent upon a study of the drawings, the specification, and the following claims. For purposes of clarity, the same reference numbers will be used in the drawings to identify similar elements. It should be understood that one or more steps within a method may be executed in a different order (or concurrently) without altering the principles of the invention.

Printed two-dimensional materials, derived from solution-processed inks, offer scalable and cost-effective routes to mechanically flexible optoelectronics. With micron-scale control and broad processing latitude, aerosol-jet printing (AJP) is of particular interest for all-printed circuits and systems.

In the invention, AJP is utilized to achieve ultrahigh-responsivity photodetectors including well-aligned, percolating networks of semiconducting MoS₂ nanosheets and graphene electrodes on flexible polyimide substrates. Ultrathin (≈1.2 nm thick) and high aspect ratio (≈1 μm lateral size) MoS₂ nanosheets are obtained by electrochemical intercalation followed by megasonic atomization during AJP, which not only aerosolizes the inks but also further exfoliates the nanosheets. The incorporation of the high boiling point solvent terpineol into the MoS₂ ink is critical to achieving a highly aligned and flat thin-film morphology following AJP as confirmed by grazing incidence wide angle X-ray scattering and atomic force microscopy. Following AJP, curing is achieved with photonic annealing, which yields quasi-ohmic contacts and photoactive channels with responsivities exceeding 10³ A/W that outperform previously reported all-printed visible photodetectors by over 3 orders of magnitude. Megasonic exfoliation coupled with properly designed AJP ink formulations enables the superlative optoelectronic properties of ultrathin MoS₂ nanosheets to be preserved and exploited for the scalable additive manufacturing of mechanically flexible optoelectronics.

Specifically, in one aspect, the invention relates to a nanomaterial ink, comprising at least one solvent; and at least one 2D semiconductor dispersed in the at least one solvent.

In some embodiments, the nanomaterial ink further comprises at least one ink additive that is adapted to affect at least one ink property including substrate wetting, rheology, particle aggregation, particle stability, phase stability, UV stability, fluorescence, ink drying dynamics, electrical properties, pH stability, foaming, and oxidation.

In some embodiments, the at least one ink additive comprises surfactants including sodium cholate, sodium dodecylsulfate, and/or cetyl trimethylammonium bromide; or polymers including polyvinylpyrrolidone, ethyl cellulose, nitrocellulose, nanocellulose, and/or poloxamers. In some embodiments, the ink additive contains polyvinylpyrrolidone, which may coat the nanosheets.

In some embodiments, the at least one solvent comprises water; low boiling point alcohols including ethanol, isopropyl alcohol, and/or 2-butanol; polar aprotic solvents including acetone, acetonitrile, N-methyl pyrrolidone, dimethylformamide, N-cyclohexyl-2-pyrrolidone, propylene carbonate, dimethyl sulfoxide, tetrahydrofuran, and/or dihydrolevoglucosenone; high boiling point organic solvents including ethylene glycol, terpineol, and/or dibutyl phthalate; and/or other organic solvents including toluene, xylene, ethyl lactate, and/or cyclohexanone.

In some embodiments, the at least one 2D semiconductor comprises nanoparticles comprising nanosheets, nanoflakes, nanofibers, nanotubes, or combinations of them.

In some embodiments, the at least one 2D semiconductor comprises elemental semiconductors including phosphorene, germanene, tellurine, selenine, and/or stanine; monochalcogenides including GeS, InSe, GaTe, PbTe, SnS, and/or SnSe; dichalcogenides including MoS₂, WSe₂, TaS₂, ReS₂, and/or MoTe₂; trichalcogenides including NbSe₃, GaInS₃, Bi₂Se₃, and/or In₂Se₃; 2D semiconducting oxides such as MnO₃ and/or V₂O₅; and/or semiconducting MXenes including Mn₂CO₂, Ti₂C, Sc₂CF₂, and/or Cr₂CF₂.

In some embodiments, the at least one 2D semiconductor is obtained by electrochemical intercalation, and exfoliation.

In some embodiments, the exfoliation comprises megasonic exfoliation.

The nanomaterial ink of claim 6, wherein the at least one 2D semiconductor has thicknesses at a single-nanometer scale and lateral sizes at a micron-scale.

In some embodiments, the at least one 2D semiconductor has the thicknesses of less than about 2 nm, and the lateral sizes of about 0.5-3 μm.

In some embodiments, the nanomaterial ink is applicable for drop casting, spin coating, dip coating, spray coating, blade coating, inkjet printing, aerosol jet printing, gravure printing, screen printing, electrodynamic jet printing, direct ink writing, 3D printing, microcontact printing, Langmuir-Blodgett assembly, layer-by-layer assembly, field-directed assembly, vacuum filtration assembly, and confined assembly.

In some embodiments, the nanomaterial ink is formed such that a film is formable to have percolating networks by a single printing pass, or multiple printing passes of the 2D nanomaterial ink.

In another aspect, the invention relates to a method of forming a nanomaterial ink, comprising providing at least one 2D semiconductor; and dispersing the at least one 2D semiconductor in at least one solvent to form the nanomaterial ink.

In some embodiments, the at least one solvent comprises water; low boiling point alcohols including ethanol, isopropyl alcohol, and/or 2-butanol; polar aprotic solvents including acetone, acetonitrile, N-methyl pyrrolidone, dimethylformamide, N-cyclohexyl-2-pyrrolidone, propylene carbonate, dimethyl sulfoxide, tetrahydrofuran, and/or dihydrolevoglucosenone; high boiling point organic solvents including ethylene glycol, terpineol, and/or dibutyl phthalate; and/or other organic solvents including toluene, xylene, ethyl lactate, and/or cyclohexanone.

In some embodiments, said providing the at least one 2D semiconductor comprises electrochemically intercalating crystalline domains of a layered semiconductor material to obtain an intercalated crystal or powder; and pre-exfoliating the intercalated crystal semiconductor using bath sonication to obtain the at least one 2D semiconductor. In some embodiments, the minimum requirement for intercalation is a layered crystalline material that is electrically connected to the electrochemical cell. In addition, beyond a monolithic single crystal or polycrystal, pressed pellets of 2D powders can also be utilized to practice the invention.

In some embodiments, the at least one 2D semiconductor comprises nanoparticles comprising nanosheets, nanoflakes, nanofibers, nanotubes, or combinations of them.

In some embodiments, the at least one 2D semiconductor comprises elemental semiconductors including black phosphorus, germanene, tellurine, and/or selenine; monochalcogenides including GeS, InSe, GaTe, PbTe, SnS, and/or SnSe; dichalcogenides including MoS₂, WSez, TaS₂, ReS₂, and/or MoTe₂; trichalcogenides including NbSe₃, GaInS₃, Bi₂Se₃, and/or In₂Se₃; 2D semiconducting oxides such as MnO₃ and/or V₂O₅; and semiconducting MXenes including Mn₂CO₂, Ti₂C, Sc₂CF₂, and/or Cr₂CF₂.

In some embodiments, the method further comprises megasonically exfoliating the nanomaterial ink.

In some embodiments, the at least one 2D semiconductor has thicknesses at a single-nanometer scale and lateral sizes at a micron-scale.

In some embodiments, the at least one 2D semiconductor has the thicknesses of less than about 2 nm, and the lateral sizes of about 0.5-3 μm.

In some embodiments, said megasonic exfoliation of the nanomaterial ink is performed in a container containing one or several piezoelectric transducers.

In some embodiments, said megasonic exfoliation of the nanomaterial ink is performed in a container containing a single piezoelectric transducer with a resonant frequency larger than 350 kHz, such as but not limited to 950 kHz or 1.65 MHz.

In some embodiments, said megasonic exfoliation of the nanomaterial ink is performed in a container containing an array of piezoelectric transducers, each with an independent resonant frequency larger than 350 kHz, such as but not limited to 950 kHz or 1.65 MHz. In some embodiments, the transducers can all be same (nominal) frequency or different nominal frequencies. Each crystal inherently has unique frequency (e.g. 956, 955, 945, 947 kHz are all “950 kHz crystal”) but one could also create an array of 450 kHz, 950 kHz, 1.2 MHz and 1.6 MHz crystals, for example.

In some embodiments, said megasonic exfoliation of the nanomaterial ink is performed in a container containing one or several piezoelectric transducers, and the ink is placed directly into the container for exposure to the megasonic acoustic energy.

In some embodiments, said megasonic exfoliation of the nanomaterial ink is performed in a container containing one or several piezoelectric transducers and an acoustic medium including water.

In some embodiments, said megasonic exfoliation of the nanomaterial ink is performed in a container containing one or several piezoelectric transducers and an acoustic medium including water, in which the nanomaterial ink is placed in a secondary container that is submerged in the acoustic medium and is designed to transmit megasonic frequency.

In some embodiments, said megasonic exfoliation of the nanomaterial ink is performed in a megasonic container including one or several piezoelectric transducers and an acoustic medium including water, in which the nanomaterial ink is placed in a thin-walled plastic container that is held at the surface of the acoustic medium or is submerged in the acoustic medium.

In some embodiments, said megasonic exfoliation of the nanomaterial ink is performed in a megasonic container including one or several piezoelectric transducers and an acoustic medium including water, in which the nanomaterial ink is placed in a thin-walled plastic container that may or may not be permeable to air.

In some embodiments, the nanomaterial ink may be placed directly into the container, although this may be subjected to solvent compatibility/corrosion issues.

In another embodiment, instead of placing the ink directly into the container, we usually use an acoustic medium including water. If water is used as an acoustic medium, the nanomaterial ink is placed in a secondary container. This may be a secondary tank or liner, which has to be carefully engineered to allow transmission of the acoustic energy through the material of the tank/liner. Thin plastic containers, i.e. plastic bag, can also work to contain the ink and allow transmission of acoustic energy. If the plastic bag has negligible air permeability, this approach may allow megasonication of air sensitive 2D materials.

In some embodiments, said megasonic exfoliation of the nanomaterial ink is performed using an AJP outfitted with an ultrasonic atomizer that operates at a frequency greater than 350 kHz, such as 1.65 MHz.

In yet another aspect, the invention relates to an electronic device or an optoelectronic device, either comprising at least one element formed of the nanomaterial ink on a substrate.

In some embodiments, the substrate comprises a rigid substrate or a flexible substrate.

In some embodiments, the at least one element is thermally annealed or photonically annealed.

In some embodiments, the optoelectronic device further comprises electrodes coupled with the at least one element.

In some embodiments, the electrodes are formed by gas phase deposition of a metal or a stack of metals including gold, chromium, indium, nickel, and titanium.

In some embodiments, the electrodes are formed by growth of a conductive material including graphene, MoO₃, and NbS₂.

In some embodiments, the electrodes are formed by depositing a conductive ink comprising at least one active material including metal nanoparticles or metal complexes including gold, silver, copper, nickel, palladium, and/or platinum; liquid metals including eGaIn; carbon nanomaterials including carbon nanotubes, graphene, fullerenes, graphene oxide, and/or reduced graphene oxide; conductive polymers including poly(3,4-ethylenedioxythiophene) polystyrene sulfonate (PEDOT:PSS), polyaniline (PANI), polypyrrole (PPy), polyacetylene, and/or polythiophene (PT); and conductive 2D materials including 1T-MoS₂, NbS2, and/or Ti3C2Tx MXenes.

In some embodiments, the electronic device is a transistor, a memristor, a diode, a power converter, a sensor, a battery, a resistor, integrated circuit elements, or combinations of them. In some embodiments, the optoelectronic device is a photodetector, a photosensor, a photodiode, a solar cell, a phototransistor, a light-emitting diode, a laser diode, integrated optical circuit (IOC) elements, a photoresistor, a charge-coupled imaging device, or combinations of them.

In some embodiments, the at least one element is formed by the AJP, during which megasonic atomization induces exfoliation and yields a high fraction of monolayer nanosheets of the at least one 2D semiconductor.

In some embodiments, the optoelectronic device has responsivities exceeding 10³ A/W that outperforms previously reported all-printed visible photodetectors by over 3 orders of magnitude.

In one aspect, the invention relates to a method of forming an optoelectronic device, comprising forming at least one element on a substrate with the nanomaterial ink; and annealing the at least one element to decompose the solvent and enhance electrical contact between nanoparticles of the at least one 2D semiconductor in the at least one element.

In some embodiments, the method further comprises forming electrodes with a graphene ink, wherein the electrodes are coupled with the at least one element.

In some embodiments, said forming the at least one element is performed with aerosol jet printing (AJP), during which megasonic atomization induces exfoliation and yields a high fraction of monolayer nanosheets of the at least one 2D semiconductor

In some embodiments, said annealing the at least one element is performed with thermal annealing or photonic annealing.

Among other things, the invention has at least the following advantages.

Megasonic exfoliation of electrochemically exfoliated materials results in nanosheets with a tight distribution of thicknesses and a high yield of monolayers. This technique yields a higher degree of size monodispersity than incumbent methods such as horn sonication, bath ultrasonication, and shear mixing.

Megasonic exfoliation conserves the mass of exfoliated material in solution and increases the yield of monolayers relative to the starting bulk material, which directly overcomes the limitations of centrifugation-based techniques such as liquid cascade centrifugation and density gradient ultracentrifugation. These centrifugal schemes obtain monolayers in the solution by sedimenting thick nanosheets, leading to a significant loss in mass as the majority of nanosheets are discarded as waste. Additionally, centrifugation can only isolate the preexisting population of monolayers from the output of the primary ultrasonication exfoliation step, and thus does not increase the yield of monolayer nanosheets.

Formulation of a megasonically exfoliated MoS₂ ink containing terpineol allows the deposition of a highly aligned and flat thin-film morphology through AJP. Flatly stacked morphologies of high-aspect ratio nanosheets are typically difficult to achieve, as laterally large flakes typically crumple upon deposition out of solution.

AJP enables the deposition of inks containing laterally large (>1 μm length) nanosheets in highly aligned thin films. In contrast, inkjet printing of this same ink results in rapidly clogged cartridges that cannot be reused. AJP also uses ink more efficiently than techniques like screen printing and spin coating.

One-step photonic annealing of AJP photodetectors based on megasonically exfoliated MoS₂ nanosheets with printed graphene electrodes results in conductive and photoactive devices. This approach circumvents the need for high-temperature annealing while still removing resistive residual solvents and polymers from the printed materials. Low-temperature photonic annealing enables processing compatibility with a wider range of plastic substrates beyond the typical polyimide (Kapton). Photonic annealing also only takes milliseconds to complete, which is 6 orders of magnitude faster than thermal annealing.

Photonic annealing promotes nanosheet intermixing at the interfaces between semiconducting MoS₂ and conductive graphene, which results in quasi-ohmic electrical contact between the two materials that also improves optoelectronic device performance.

Nanomaterials synthesis for 2D material monolayer inks: The megasonic exfoliation technique developed here provides a new, inexpensive route for 2D monolayer exfoliation and ink formulation. Thus far, only primary exfoliation techniques (e.g., horn sonication, bath ultrasonication, shear mixing, etc.) have been investigated, and these resulting dispersions contain minuscule amounts of monolayers. Subsequent monolayer enrichment has required processing steps that simply remove under-exfoliated materials. Megasonic exfoliation promotes the conversion of under-exfoliated nanosheets into monolayers.

Printed optoelectronics: This technology addresses the challenge of scalable production of high performing, 2D-based optoelectronics. Printable, solution-processed 2D materials present an advantage over chemical vapor deposition and mechanical exfoliation not only in terms of cost and ease of mass production but also in expanding compatible substrates and platforms. Furthermore, AJP is an advantageous method compared to inkjet printing, since it requires less rheological tuning and has higher spatial resolution, which is ideal for fabricating all components of optoelectronic devices and circuits. The aforementioned advances in obtaining high-quality, high aspect ratio nanoflakes and subsequent ink formulation enables well-aligned nanoflake morphologies after printing, which establishes a new state-of-the-art in all-printed visible photodetectors.

The invention may have widespread applications in nanomaterials synthesis, printed optoelectronics, flexible photodetectors, wearable sensors, photodetectors, thin-film transistors, neuromorphic computing devices, and the likes.

These and other aspects of the invention are further described below. Without intent to limit the scope of the invention, exemplary instruments, apparatus, methods, and their related results according to the embodiments of the invention are given below. Note that titles or subtitles may be used in the examples for convenience of a reader, which in no way should limit the scope of the invention. Moreover, certain theories are proposed and disclosed herein; however, in no way they, whether they are right or wrong, should limit the scope of the invention so long as the invention is practiced according to the invention without regard for any particular theory or scheme of action.

### Example

### All-Printed Ultrahigh-Responsivity MoS₂ Nanosheet Photodetectors Enabled by Megasonic Exfoliation

In this exemplary example, we report ultrahigh-responsivity photodetectors on flexible polyimide substrates via aerosol jet printing (AJP) of percolating MoS₂ nanosheet photoactive networks and graphene electrodes. To produce aerosolized ink droplets, AJP utilizes a megasonic atomizer that operates at megahertz frequencies, compared to the kilohertz frequencies that are commonly utilized for LPE ultrasonic processing. This higher frequency megasonic regime enables more controlled, localized cavitation compared to ultrasonication. In this manner, megasonic exfoliation yields reduced MoS₂ nanosheet thickness approaching the single-nanometer scale while maintaining large lateral sizes at the micron-scale. Since the resulting high aspect ratio nanosheets are susceptible to crumpling during printing and subsequent solvent evaporation, carefully designed AJP ink formulations based on the high boiling point solvent terpineol are critical to achieving a well-aligned and flat percolating network. Following photonic curing, the high-conductivity MoS₂ percolating network forms quasi-ohmic contacts to the printed graphene contacts, thus enabling photodetectors with responsivities exceeding 10³ A/W that outperform previously reported all-printed visible photodetectors by over 3 orders of magnitude. This performance can be attributed to megasonic exfoliation, which yields high aspect ratio nanosheets including a significant fraction of monolayers, as confirmed by optical absorbance, Raman spectroscopy, and photoluminescence (PL) spectroscopy. The well-stacked, interconnected nanosheet morphology following AJP is confirmed by grazing incidence wide angle X-ray scattering (GIWAXS) and atomic force microscopy (AFM). Spatially resolved photocurrent (SPCM) imaging and variable temperature charge transport measurements further show that photonic annealing improves the electrical contact between the percolating MoS₂ photoactive channel and the graphene electrodes. Overall, this additive manufacturing methodology enables the superlative optoelectronic properties of ultrathin and high aspect ratio MoS₂ nanosheets from megasonic exfoliation to be utilized for all-printed, mechanically flexible photodetector technology.

### Materials and Methods

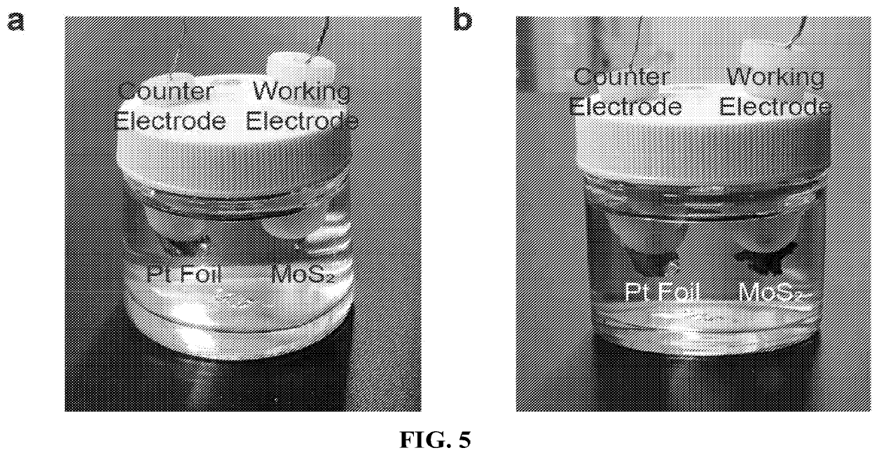

MoS₂ Ink Preparation. A custom two-terminal electrochemical cell was assembled to achieve controlled electrochemical intercalation of MoS₂ (FIG. 5). First, the working electrode was constructed by clamping a cleaved sliver of bulk single-crystal MoS₂ (synthetic MoS₂, 2D Semiconductors) between two pieces of platinum foil. A separate piece of platinum foil acted as the counter electrode. The two electrodes were submerged in a 5 mg/mL solution of tetraheptyl ammonium bromide (THAB) (≥99%, Sigma Aldrich) in acetonitrile (99.8% anhydrous, Sigma Aldrich) that was prepared in a nitrogen-filled glovebox. A three-step voltage profile was applied: first −2 V for 5 min, then −5 V for 10 min, and finally −10 V for 1 h. Following intercalation, the expanded MoS₂ crystals were rinsed with isopropyl alcohol (IPA) (Fisher Scientific) to remove residual electrolyte.

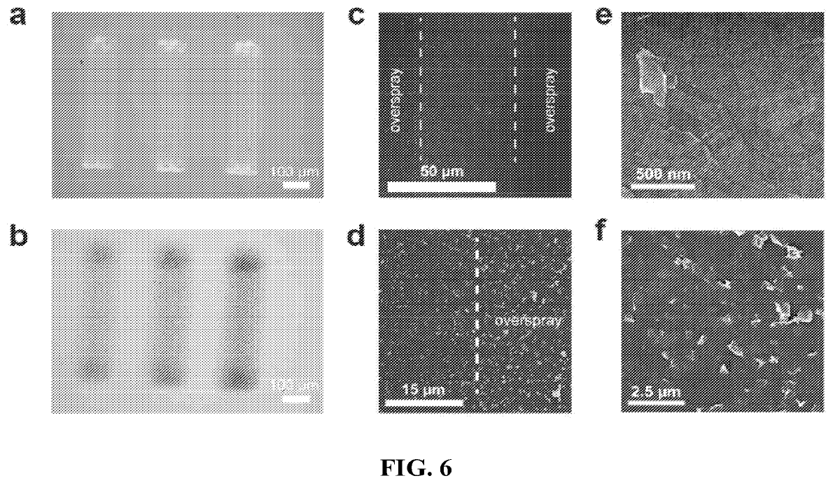

Several intercalated crystals totaling ≈40 mg were used to make a concentrated ink. The intercalated crystals were placed in a solution of 0.9 g of polyvinylpyrrolidone (PVP) (mass average molar mass ≈29,000 Da, Sigma Aldrich) in 40 mL of dimethylformamide (DMF) (99.8% anhydrous, Sigma Aldrich) and subsequently bath sonicated for about 20 to 40 min. In the first solvent exchange cycle, the exfoliated MoS₂ was centrifuged at 3.4 krad/s (1 rad/s≈9.5 rpm) for 1.5 h. Then, the PVP/DMF supernatant was removed and replaced with IPA. This step was repeated in a second cycle to further remove residual PVP/DMF. After the second washing step, 10 mL of IPA was added to the collected pellet before bath sonicating for ≈10 min. To eliminate unexfoliated materials, the dispersion was centrifuged at 780 krad/s for 5 min (Avanti J-26 XP, Beckmann Coulter) and the supernatant was collected. To formulate an ink for AJP, about 5 to 7% by volume of terpineol (Sigma Aldrich) was added to prevent complete evaporation of the aerosol droplets before they reached the substrate (panels c-f of FIG. 6).

Graphene Ink Preparation. Graphene/ethyl cellulose (EC) powder was prepared following a previously reported procedure. The exfoliated graphene/EC powder containing 40% by mass graphene was used to prepare the graphene ink. In particular, the graphene/EC powder was redispersed in ethanol at a loading of 10 mg/ml, and then ultrasonicated using a horn tip at low power (10% amplitude) for 1 h to gently break up graphene aggregates. After sonication, the dispersion was filtered through a 3.1 μm syringe filter. For AJP, 1.5 mL of graphene ink was formulated with 10% by volume terpineol.

Photodetector Printing and Processing. All components of the photodetectors were printed using a commercial AJP (Aerosol Jet 200. Optomec). For both the graphene electrodes and the MoS₂ channel, a 150-μm diameter tip was used, the megasonic atomizer bath was held at 10° C., and the stage was heated to 60° C. The inks were aerosolized at the minimum necessary megasonic power, typically between 0.3 and 0.45 mA, and printed with a carrier gas flow rate of 15 sccm and sheath gas flow rate of 60 sccm. Bottom graphene electrodes were first printed on polyimide at (2 to 4) mm/sec with a single pass, after which MoS₂ channels were printed at 4 mm/sec with 50 μm length and 50 or 500 μm widths. For the thermally annealed devices, the graphene electrodes were first photonically annealed (Sinteron 2000, Xenon) at 2.8 kV for 1.36 ms (4.06 J/cm²) preceding MoS₂ printing. Thermal annealing of the MoS₂ channel was carried out in a tube furnace at 280° C. with Ar flowing at 50 sccm (Lindberg Blue/M, Thermo Scientific). A single photonic annealing step at 2.8 kV for 1.36 ms was used for the photonically annealed devices, simultaneously curing the MoS₂ channel and the graphene electrodes.

Physical and Chemical Characterization. Optical absorbance spectra were measured with an ultraviolet-vis spectrophotometer (Cary 5000, Agilent) using plastic cuvettes (path length=1 cm) containing MoS₂ inks diluted by 100-fold. For AFM, Raman, and PL analysis, the MoS₂ flakes were drop-casted and thermally annealed at 400° C. to remove residual PVP and other adsorbates. Raman and PL spectra were collected using a Horiba Xplora Raman/PL system with a 532 nm laser. Nanosheet size histograms were obtained from topography images gathered using an Asylum Cypher AFM operated in a non-contact tapping mode that were then processed with Gwyddion software. Optical micrographs were obtained from an optical microscope (BX51M, Olympus). XPS was measured using a Thermo Fisher ESCALAB 250Xi with the resulting data being processed with Avantage software. The XPS spectra were charge shifted to the adventitious carbon reference peak at 248.8 eV. GIWAXS was performed at the 11-BM complex materials science beamline at the National Synchrotron Light Source-II (Brookhaven National Laboratory) at a beam energy of 13.5 keV with a Pilatus 800k imaging detector at a nominal detector distance of 261 mm. The beam center and detector distance were calibrated using a silver behenate standard, and the angle of incidence was 0.16°.

Electrical Characterization. Photoresponse was measured on a probe station (LakeShore CRX 4K) in ambient conditions with a Keithley 2400 source meter. Temperature-dependent measurements were conducted on the same probe station by setting the stage temperature. The devices were illuminated by a 515.6 nm wavelength laser, and the laser power was controlled by setting the diode current (LP520MF100, Thor Labs). For the spectrally resolved photocurrent measurements, the wavelengths measured were between 530 nm and 910 nm while the power was fixed at 10 μW. The detailed calibration protocol for the illumination intensity has been previously reported. Response time measurements were captured by modulating the laser with a waveform generator and measuring the source-drain current signal with an oscilloscope and preamplifier.

The scanning photocurrent measurements were conducted using a scanning confocal microscope (WiTec, Alpha 300R) in ambient conditions. The output of a supercontinuum laser (SuperK EVO, NKT Photonics) was directed to an acousto-optic tunable filter (AOTF) to select the excitation wavelength and to modulate the power at 2.737 kHz. The laser was fiber-coupled into the confocal microscope and focused onto the sample with a collimating lens and a 50× objective. Source and drain electrodes were contacted with radio frequency (RF) microprobes (Quarter Research and Development, 20340) terminated with SMA (SubMiniature version A) connectors, and the photocurrent was transmitted with SMA to BNC RF cable with RG-400 coax. The digital to analog converter (DAC) output of the lock-in amplifier (Model 7265, Signal Recovery) was connected to the drain electrode to provide various biases. The photocurrent was collected at the source contact and was amplified by a variable gain current preamplifier (Model 1211, DL instruments), while the lock-in amplifier was used to detect the AC photocurrent signal generated by the laser power modulation. SPCM images were acquired by raster scanning the samples with 200 nm steps via a piezo-driven stage with an integration time of 15 ms at each pixel.

### Results and Discussion

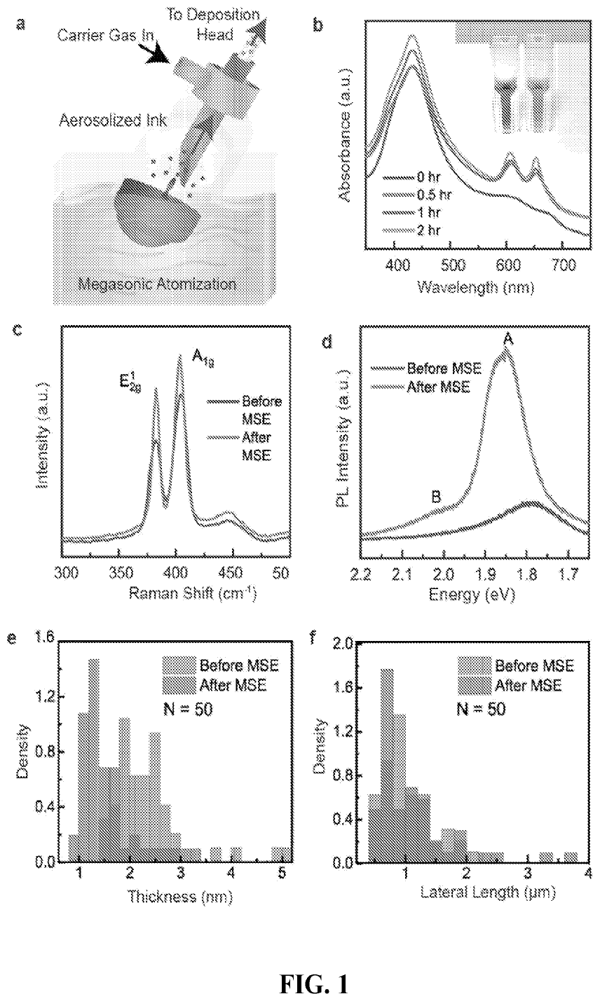

Preceding megasonic exfoliation, bulk MoS₂ single crystals were electrochemically intercalated with tetraheptyl ammonium bromide (THAB), as confirmed by crystal expansion (FIG. 5). The intercalated crystal was then pre-exfoliated using bath sonication in dimethylformamide (DMF) with polyvinylpyrrolidone (PVP) as a stabilizing polymer, after which a printable ink was prepared in isopropyl alcohol and terpineol. During AJP, the MoS₂ inks are aerosolized into droplets by a megasonic atomizer operating at a frequency of 1.65 MHz. When printing, the droplets are transported to the deposition head by a carrier gas and focused onto the substrate by a stream of sheath gas (panel a of FIG. 1). In contrast, when not printing, the droplets recondense in the megasonic atomizer chamber, thus allowing for extended exposure of the ink to megahertz frequencies, resulting in megasonic exfoliation. Within 30 min, megasonic exfoliation yields thinning of the MoS₂ flakes, as reflected in a blue-shifted A-exciton optical absorbance peak (from 679 nm to 653 nm) (panel b of FIG. 1). It should be noted that the A-exciton blueshift does not change beyond 30 min of megasonic exfoliation, although a gradual increase in optical absorbance occurs due to monotonically increasing ink concentration as the solvent evaporates over time. Consistent with the A-exciton peak shift, the megasonically exfoliated ink exhibits a vibrant green hue compared to the brownish green color of the starting ink (panel b of FIG. 1, inset).

The improved exfoliation following megasonic aerosolization is corroborated by Raman spectroscopy, photoluminescence (PL), and AFM. In particular, the difference between the A_{1g} and E¹_{2g} Raman spectral peaks decreases from 22.5 cm⁻¹ to 20.6 cm⁻¹ (panel c of FIG. 1), which is consistent with a decreased number of MoS₂ layers and suggests the final dispersion predominantly includes monolayer and bilayer MoS₂ nanosheets. Likewise, the A-exciton PL peak shifts from 1.79 eV to 1.86 eV, in agreement with the corresponding optical absorbance peaks (panel d of FIG. 1). The slightly increased B-exciton peak at 2.02 eV is associated with a higher order spin-orbit split state and can be explained by non-radiative recombination due to aerosolization-induced defects, in agreement with previously reported AJP MoS₂ films. For AFM analysis, the MoS₂ flakes were drop-casted and thermally annealed at 400° C. in an effort to remove residual PVP and other adsorbates. The resulting AFM-derived histogram shows that the median flake thickness decreases from 2.2 nm to 1.3 nm (panel e of FIG. 1). Significantly, megasonic exfoliation does not compromise the lateral size distribution, with the MoS₂ flakes averaging ≈1 μm in lateral size before and after megasonic aerosolization (panel f of FIG. 1). While flake fracture and thus lateral size reduction are known to occur for ultrasonic exfoliation of 2D materials at kilohertz frequencies, the preservation of the large lateral size distribution following megasonic exfoliation may be attributed to the more controlled cavitation at megahertz frequencies.

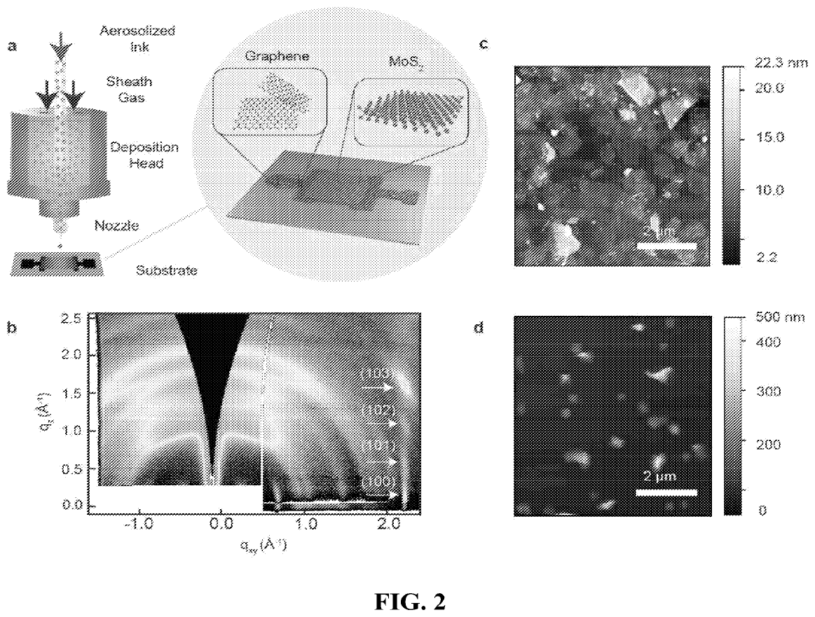

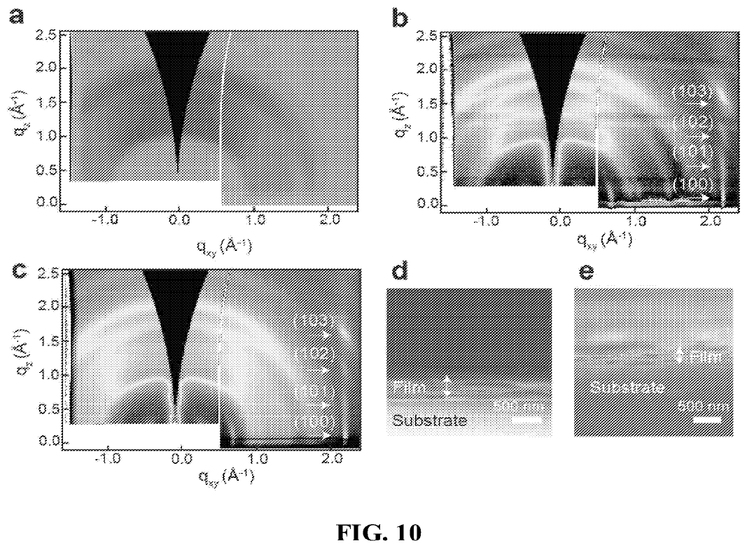

Since MoS₂ transitions from an indirect to a direct bandgap at the monolayer regime and thus is ideal for optoelectronic applications in the atomically thin limit, we pursued the fabrication of all-printed photodetectors to illustrate the utility of megasonically exfoliated MoS₂. Towards this end, AJP was used to deposit megasonically exfoliated MoS₂ as the channel material between AJP-printed graphene electrodes (panel a of FIG. 2). Despite a large background signal from the polyimide substrate, GIWAXS clearly exhibits features of the MoS₂ (100), (101), (102), and (103) planes, revealing uniaxial texture along the c-axis that confirms the deposition of flat, stacked MoS₂ nanosheets (panel b of FIG. 2 and FIG. 10). Face-on deposition of thin and laterally large MoS₂ nanosheets is achieved by including terpineol as a high boiling point solvent in the AJP MoS₂ ink formulation (panel c of FIG. 2). Without terpineol, the MoS₂ nanosheets crumple into ball-like structures and significantly overspray due to dry printing, as revealed by AFM (panel d of FIG. 2 and FIG. 6).

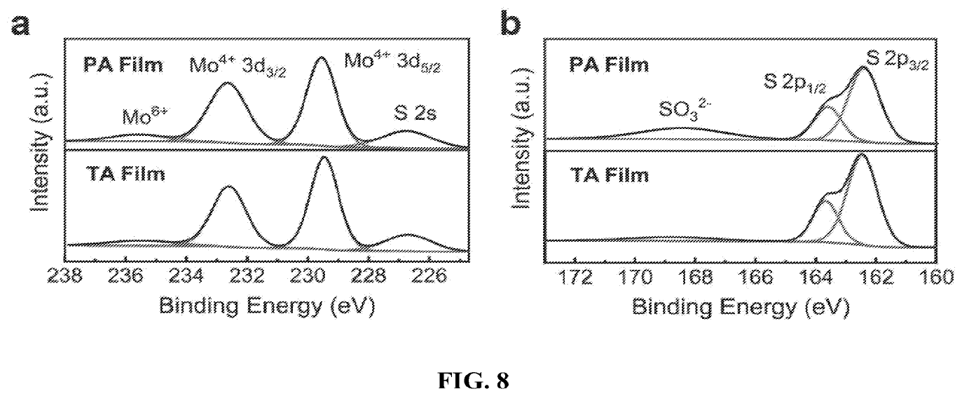

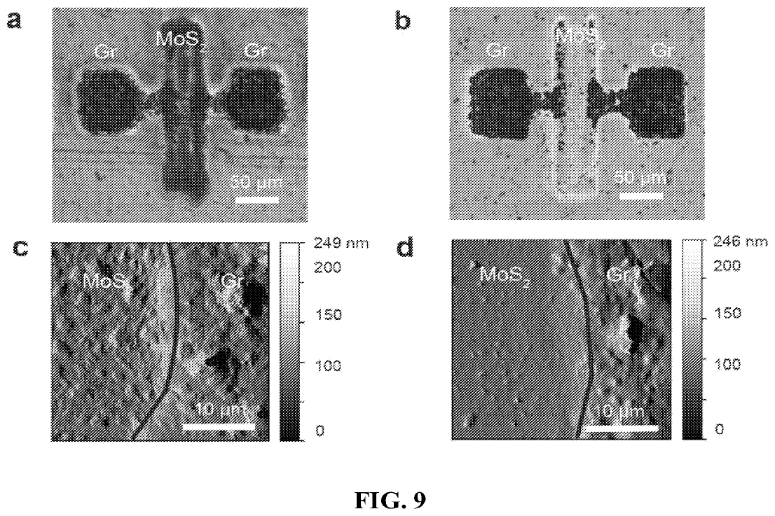

Mild thermal annealing (TA) at 280° C. for 1 h in an Ar atmosphere or photonic annealing (PA) at 2.8 kV for 1.36 ms (4.06 J/cm²) in ambient conditions can be used to remove residual PVP and other adsorbates from the printed MoS₂ nanosheets while maintaining compatibility with flexible polyimide substrates. PA differs from TA in its use of a high-intensity, broadband spectrum of pulsed light to locally and rapidly heat the light-absorbing MoS₂ and graphene on the thermally insulating polyimide substrate. These TA and PA processing conditions have been previously reported to limit the formation of metallic molybdenum oxides for MoS₂. Additionally, these TA and PA processing conditions are sufficient to simultaneously remove both ethyl cellulose (EC) used in the graphene electrode inks and PVP from the MoS₂ channel, thus ensuring electrically conductive percolating networks for the entire MoS₂/graphene heterostructure. X-ray photoelectron spectroscopy (XPS) reveals that the two annealing methods result in chemically similar films (FIG. 8). More notably, PA results in a rougher film morphology and leads to greater intermixing between the graphene and MoS₂ nanosheets as a result of the rapid gas evolution during EC and PVP decomposition (FIG. 9). Despite the rougher surfaces arising from PA, minimal changes are observed in the GIWAXS signal compared to as-deposited film data in panel b of FIG. 2, suggesting that the flat and stacked orientation along the c-axis is largely preserved in the final MoS₂ percolating networks (FIG. 10).

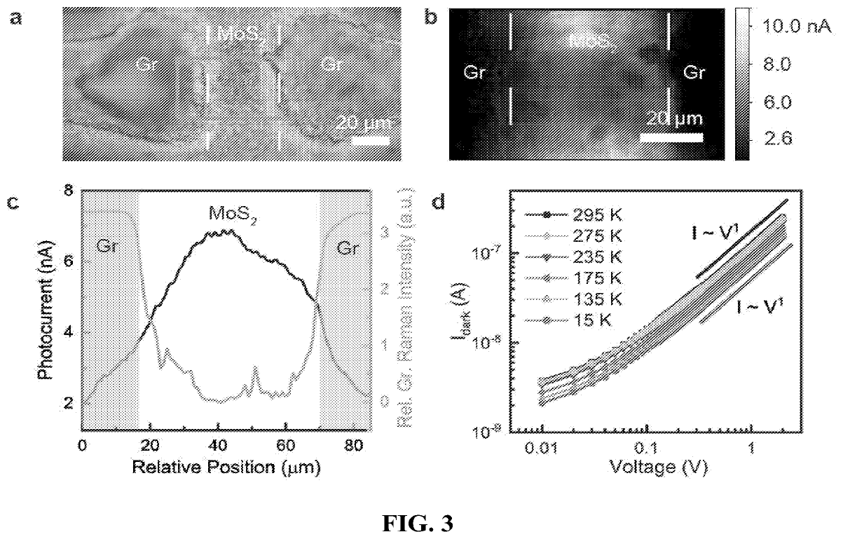

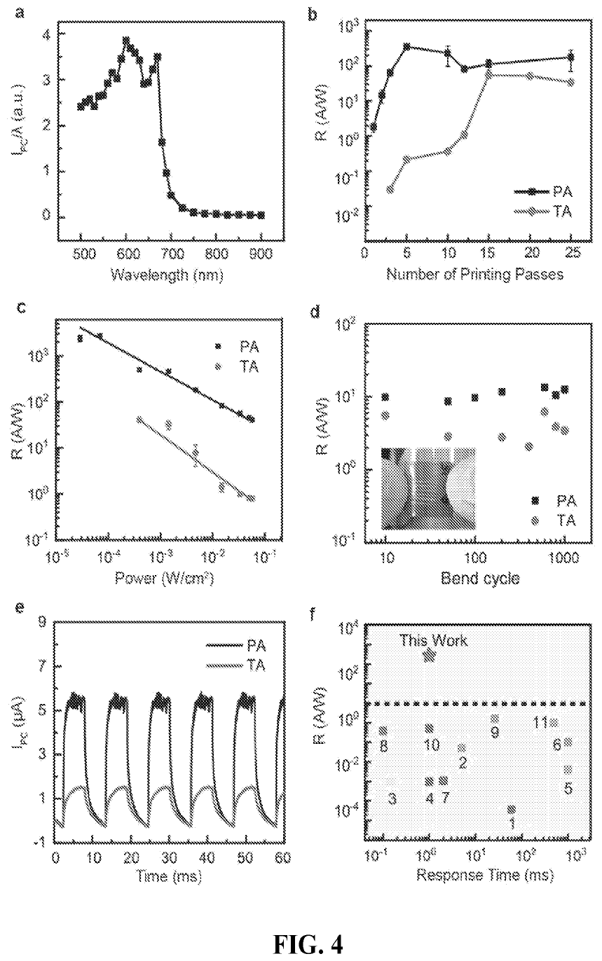

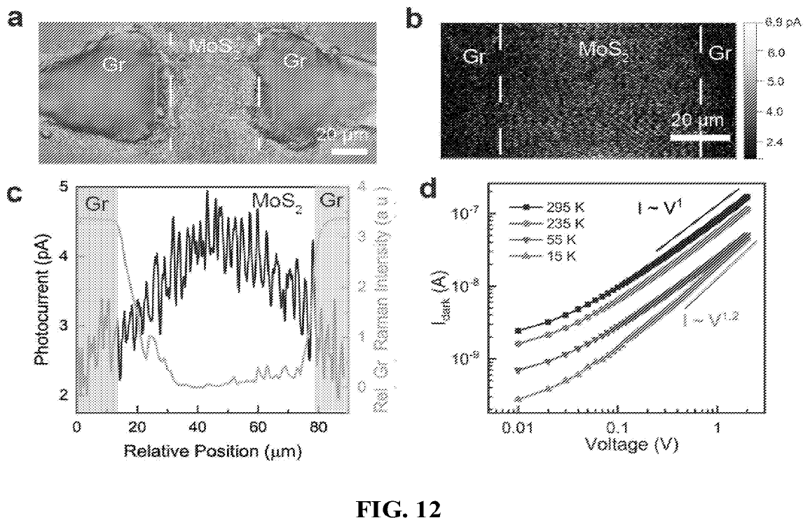

SPCM (wavelength, λ=630 nm, spot size=1.54 μm) shows that the photoresponse in the all-printed photodetectors primarily arises from the MoS₂ channel rather than the graphene electrodes (panels a-c of FIG. 3). Fluctuations in the photocurrent throughout the mapped MoS₂ channel originate from thickness variations in the printed and cured film. A larger photocurrent is observed in the PA devices compared to the TA devices. Since large photocurrent is produced at Schottky contacts, the smoother SPCM line profile observed in the PA photodetector is consistent with intimate intermixing of graphene and MoS₂ nanosheets at the channel-contact interface that results in quasi-ohmic contacts, as well as greater nanosheet interconnectivity across the channel (panels b-c of FIG. 3 and panels b-c of FIG. 12). The improved electrical contact between MoS₂ and graphene in the PA devices is further confirmed by temperature-dependent current-voltage characteristics. While PA devices exhibit linear charge transport above 0.1 V at all temperatures, the TA devices show clear deviations from linear behavior below 55 K, which is indicative of thermionic emission at the MoS₂-graphene interface in the TA devices (panel d of FIG. 4 and panel d of FIG. 12) Spectrally resolved photocurrent measurements further confirm that the photoresponse arises from optical absorption within the MoS₂ channel (panel a of FIG. 4). Specifically, the photocurrent spectral peaks at ≈600 nm and ≈670 nm are consistent with the optical absorption peaks of the megasonically exfoliated MoS₂ inks (panel b of FIG. 1). The peak at 670 nm matches the A exciton PL peak, suggesting that photocurrent results from field-induced dissociation of excitons, which is a notable observation in a solution-processed percolating film. The photocurrent increases with net photons absorbed that varies with film thickness according to the Beer-Lambert law, while the dark current increases monotonically with film thicknesses. Consequently, the photocurrent has a stronger dependence on film thickness in the small thickness limit, whereas the dark current begins to dominate when film thickness exceeds the absorption length. To optimize the tradeoff between photoresponse and dark current, we measured responsivity (R=I_{PC}/P, where I_{PC} and P are the photocurrent and the illumination power, respectively), as a function of printing passes where each pass increases the thickness by ≈20 nm. Devices including up to 25 printing passes were measured, with total film thicknesses varying from 20 nm to 500 nm. Responsivity was extracted by acquiring current-voltage characteristics up to V=40 V in dark and under illumination at λ=515.6 nm (panel b of FIG. 4, at 40 V). As expected, responsivity initially increases with thickness (i.e., number of printing passes). Then, responsivity reaches a maximum, followed by a decrease with thickness once the photocurrent saturates and the dark current begins to dominate. The peak in responsivity occurs at 5 printing passes for PA films and 15 passes for TA films, reflecting morphological differences that arise from the two annealing treatments.

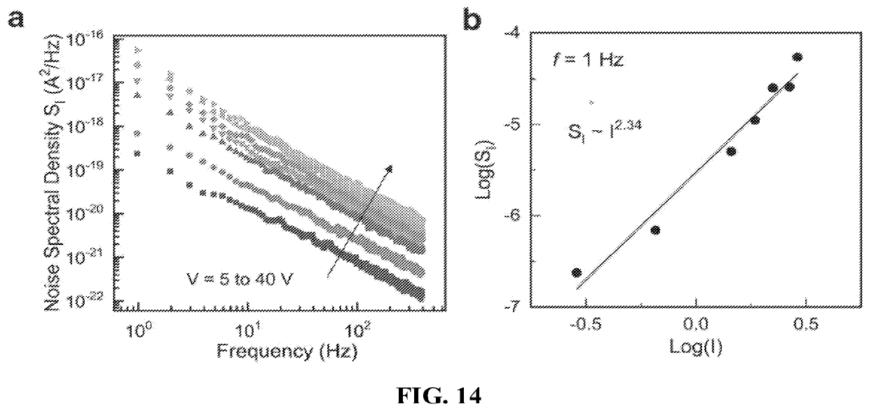

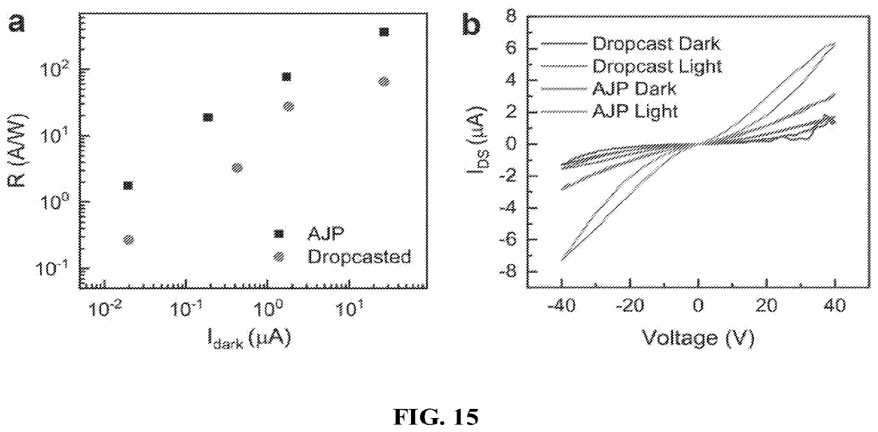

The all-printed photodetectors exhibit sublinear power dependence (R∝P^{γ}, γ=−0.6 for PA films and γ=0.8 for TA films), resulting in higher responsivities at lower powers for both types of films (panel c of FIG. 4). At low intensity (7×10⁻⁵ W/cm²), the highest responsivity for the PA devices reached 2.7×10³ A/W, resulting in internal gain of 1.13×10³. The highest gain at the lowest intensity is arising from the slowest trap lifetimes since gain varies as

$$\frac{τ ( μ V )}{{L}^{2}} ,$$

where τ, L, and μ are trap lifetime, channel length, and mobility, respectively. The measured gain at V=40 V and response time of ≈1 ms (discussed later) implies a carrier mobility of 0.7 cm²/Vs for the percolating network of printed 2D nanoflakes. We also estimate detectivity (D*) using D*=(AΔf)^{1/2}/NEP, where A is the area of the photodetector, Δf is the frequency bandwidth, NEP (=S_{I}/R) is the noise equivalent power, and S_{I} is the noise spectral density. NEP is obtained by explicit measurement of the noise spectral density (S_{I}) in dark conditions (FIG. 14) since the shot noise limit of NEP is known to artificially inflate D*, particularly in nanoscale photodetectors that have large extrinsic gain. The highest detectivity was 1.8×10⁷ Jones at an intensity of 7×10⁵ W/cm². The sublinear power dependence, which is attributed to bimolecular recombination, agrees with previously reported CVD-grown and mechanically exfoliated monolayer MoS₂ photodetectors (γ<0), but contrasts the superlinear power dependence (γ>0) in previously reported solution-processed MoS₂ and GaTe photodetectors that are explained by a two-center Shockley-Read-Hall (SRH) model. The dominance of bimolecular recombination suggests that megasonically exfoliated MoS₂ has a large fraction of direct bandgap monolayer flakes and a small density of trap states that are known to produce SRH recombination. The efficient exciton dissociation in the all-printed photodetectors may also be assisted by the large local electric fields that result from the high curvature at the edges of the 2D nanosheets in the percolating film. The importance of the morphology of the AJP percolating network was further verified by comparison with drop-casted photodetectors of similar channel thicknesses, which showed an order of magnitude lower responsivity (FIG. 15). The mechanical robustness of the all-printed, flexible photodetectors was confirmed by stable operation following 10³ bending cycles at a bending radius of 12 mm (panel d of FIG. 4).

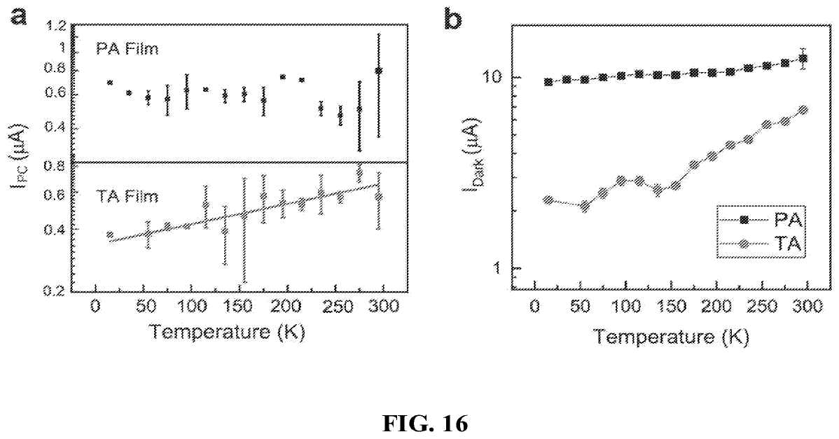

Both the TA and PA devices exhibit relatively fast response times of ≈1 ms rise time and ≈5 ms fall time at V_{DS}=20 V (panel e of FIG. 4), although a slightly slower response time is observed for the TA devices. Slower fall times than rise times are often associated with defect-induced trap states in MoS₂. A slower time constant and an increased deviation from a linear power coefficient suggest that TA results in an increased density of trap states compared to PA, possibly due to increased defects formed at elevated temperature. Additionally, temperature-dependent photocurrent measurements display a stronger temperature dependence in the TA films, pointing to the larger role of trap states (FIG. 16). A tradeoff between responsivity and time response is expected in photoconductors, where a long lifetime of trapped charges increases photocurrent gain but also slows down the temporal response. Nevertheless, our all-printed photodetectors exhibit relatively fast response times compared to the ≈1 s timescales observed in CVD-grown or mechanically exfoliated MoS₂ photodetectors with comparatively high responsivities. The net effect is that our devices show superlative performance with competitive response times and over 3 orders of magnitude higher responsivity than previously reported all-printed visible photodetectors (panel f of FIG. 4).

TABLE 1
FWHM Fitting. FWHM (from fits to a Voight function)
of the (103) peak in the radial and tangential directions,
as a function of processing and substrate.

| | Radial FWHM | Tangential FWHM |
|---|---|---|
| Sample | (Å⁻¹) | (°) |
| As-Deposited on Polyimide | 0.110 ± 0.001 | 6.2 ± 0.1 |
| As-Deposited on Si | 0.102 ± 0.001 | 5.9 ± 0.1 |
| Thermally Annealed on | 0.105 ± 0.001 | 5.6 ± 0.1 |
| Polyimide | | |
| Thermally Annealed on Si | 0.102 ± 0.001 | 5.2 ± 0.1 |
| Photonically Annealed on | 0.110 ± 0.001 | 5.9 ± 0.1 |
| Polyimide | | |

We find that substrate selection does not significantly influence the morphology of the printed films. Agreement in radial and tangential full width half maximum (FWHM) between films on an oxidized Si wafer and polyimide demonstrates that the polyimide film roughness does not significantly contribute to the peak widths (Table 1). All uncertainties are one standard deviation of the fit parameter, estimated from the covariance matrix of the fit.

TABLE 2
Literature Comparison for panel f of FIG. 4.

| Plot | | | Respon- | | |
|---|---|---|---|---|---|
| Label | | Printing | sivity | Response | Reference |
| Number | Material | Method | (A/W) | Time (ms) | Number |
| This | MoS₂ | AJP | 2730 | 1 | — |
| Work | | | | | |
| 1 | MoS₂ | Inkjet | 3.6 × 10⁻⁵ | 60 | [5] |
| 2 | MoS₂ | Inkjet | 0.05 | 5 | [6] |
| 3 | WS₂ | Inkjet | 0.001 | 0.15 | [6] |
| 4 | MoS₂ | Inkjet | 0.001 | 1 | [7] |
| 5 | MoS₂ | Electro- | 0.004 | 1000 | [8] |
| | | hydrodynamic | | | |
| 6 | WS₂ | Electro- | 0.1 | 1000 | [8] |
| | | hydrodynamic | | | |
| 7 | CNTs | Inkjet | 0.0011 | 2 | [9] |
| 8 | Polymer | Inkjet | 0.39 | 0.1 | [10] |
| 9 | Perovskite | Inkjet | 1.62 | 25.9 | [11] |
| 10 | Perovskite | Inkjet | 0.52 | 1 | [12] |
| 11 | WSe₂ | AJP | 1 | 500 | [13] |

In summary, all-printed ultrahigh-responsivity MoS₂ photodetectors have been prepared by AJP, where megasonic exfoliation during aerosolization yields a high fraction of monolayer MoS₂ nanosheets. Flake thinning with minimal flake scission occurs due to the localized cavitation produced during megasonic atomization, as corroborated by AFM, PL, and Raman spectroscopy. A well-aligned, percolating network of printed nanosheets was achieved during AJP by avoiding dry printing through the addition of the high boiling point solvent terpineol to the ink formulation. Photonic curing further yields high intermixing between the MoS₂ channel and graphene contacts, resulting in photodetectors with responsivities exceeding 10³ A/W that outperforms previously demonstrated all-printed visible photodetectors by over 3 orders of magnitude. Ultimately, this work establishes megasonic exfoliation as a viable strategy for harnessing the full optoelectronic potential of solution-processed 2D materials in a manner compatible with scalable additive manufacturing.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described to explain the principles of the invention and their practical application to enable others skilled in the art to utilize the invention and various embodiments and with various modifications as are suited to the particular use contemplated. Alternative embodiments will become apparent to those skilled in the art to which the invention pertains without departing from its spirit and scope. Accordingly, the scope of the invention is defined by the appended claims rather than the foregoing description and the exemplary embodiments described therein.

Some references, which may include patents, patent applications, and various publications, are cited and discussed in the description of this invention. The citation and/or discussion of such references is provided merely to clarify the description of the invention and is not an admission that any such reference is “prior art” to the invention described herein. All references cited and discussed in this specification are incorporated herein by reference in their entireties and to the same extent as if each reference was individually incorporated by reference.

### LIST OF REFERENCES

[1]. F. P. Garcia De Arquer, A. Armin, P. Meredith, E. H. Sargent, Nat. Rev. Mater. 2017, 2, 1.
[2]. Y. Xu, Q. Lin, Appl. Phys. Rev. 2020, 7, 011315.
[3]. M. Buscema, J. O. Island, D. J. Groenendijk, S. I. Blanter, G. A. Steele, H. S. J. Van Der Zant, A. Castellanos-Gomez, Chem. Soc. Rev. 2015, 44, 3691.
[4]. J. Kang, V. K. Sangwan, J. D. Wood, M. C. Hersam, Acc. Chem. Res. 2017, 50, 943.
[5] J. W. T. Seo, J. Zhu, V. K. Sangwan, E. B. Secor, S. G. Wallace, M. C. Hersam, ACS Appl. Mater. Interfaces 2019, 11, 5675.
[6]. J. Kang, V. K. Sangwan, H. S. Lee, X. Liu, M. C. Hersam, ACS Photonics 2018, 5, 3996.
[7]. X. Gao, G. Bian, J. Zhu, J. Mater. Chem. C 2019, 7, 12835.
[8]. V. K. Sangwan, M. C. Hersam, Annu. Rev. Phys. Chem. 2018, 69, 299.
[9]. A. G. Kelly, D. O'Suilleabhain, C. Gabbett, J. N. Coleman, Nat. Rev. Mater. 2021, 7, 217.
[10]. Z. Lin, Y. Liu, U. Halim, M. Ding, Y. Liu, Y. Wang, C. Jia, P. Chen, X. X. Duan, C. Wang, F. Song, M. Li, C. Wan, Y. Huang, X. X. Duan, Nature 2018, 562, 254.
[11]. P. Li, Q. Hao, J. Liu, D. Qi, H. Gan, J. Zhu, F. Liu, Z. Zheng, W. Zhang, P. Li, Q. Y. Hao, D. Y. Qi, H. B. Gan, J. Q. Zhu, W. J. Zhang, J. D. Liu, F. Liu, Adv. Funct. Mater. 2021, 32, 2108261.
[12]. R. Nagarajan, S. Awad, K. R. Gopi, in Dev. Surf. Contam. Clean.—Methods Remov. Part. Contam., William Andrew Publishing, 2011, pp. 31-62.
[13]. R. F. Hossain, I. G. Deaguero, T. Boland, A. B. Kaul, npj 2D Mater. Appl. 2017, 1, 1.
[14]. H. Li, Q. Zhang, C. C. R. Yap, B. K. Tay, T. H. T. Edwin, A. Olivier, D. Baillargeat, Adv. Funct. Mater. 2012, 22, 1385.
[15]. N. Saigal, S. Ghosh, Appl. Phys. Lett. 2016, 109, 122105.
[16]. X. Feng, Y. Li, L. Wang, S. Chen, Z. G. Yu, W. C. Tan, N. Macadam, G. Hu, L. Huang, L. Chen, X. Gong, D. Chi, T. Hasan, A. V. Y. Thean, Y. W. Zhang, K. W. Ang, Adv. Electron. Mater. 2019, 5, 1900740.
[17]. C. Backes, D. Campi, B. M. Szydlowska, K. Synnatschke, E. Ojala, F. Rashvand, A. Harvey, A. Griffin, Z. Sofer, N. Marzari, J. N. Coleman, D. D. O'regan, ACS Nano 2019, 13, 7050.
[18]. R. H. Bube, Photoelectronic Properties of Semiconductors, Cambridge University Press, Cambridge, 1992.
[19]. S. Bianconi, L. J. Lauhon, H. Mohseni, Nat. Photonics 2021, 15, 714.
[20]. M. Rezaei, S. Bianconi, L. J. Lauhon, H. Mohseni, Nano Lett. 2021, 21, 9838.
[21]. O. Lopez-Sanchez, D. Lembke, M. Kayci, A. Radenovic, A. Kis, Nat. Nanotechnol. 2013, 8, 497.
[22]. S. Li, X. Chen, F. Liu, Y. Chen, B. Liu, W. Deng, B. An, F. Chu, G. Zhang, S. Li, X. Li, Y. Zhang, ACS Appl. Mater. Interfaces 2019, 11, 11636.
[23]. J. Kim, S. Kim, Y. S. Cho, M. Choi, S.-H. Jung, J. H. Cho, D. Whang, J. Kang, ACS Appl. Mater. Interfaces 2021, 13, 12221.
[24]. V. K. Sangwan, S. V. Rangnekar, J. Kang, J. Shen, H. S. Lee, D. Lam, J. Shen, X. Liu, A. C. M. de Moraes, L. Kuo, J. Gu, H. Wang, M. C. Hersam, Adv. Funct. Mater. 2021, 31, 2107385.
[25]. A. Di Bartolomeo, L. Genovese, T. Foller, F. Giubileo, G. Luongo, L. Croin, S. J. Liang, L. K. Ang, M. Schleberger, Nanotechnology 2017, 28, 214002.
[26]. R. Wadhwa, A. V Agrawal, M. Kumar, J. Phys. D. Appl. Phys. 2021, 55, 063002.
[27]. W. Zhang, J. K. Huang, C. H. Chen, Y. H. Chang, Y. J. Cheng, L. J. Li, Adv. Mater. 2013, 25, 3456.
[28]. A. C. M. de Moraes, J. Obrzut, V. K. Sangwan, J. R. Downing, L. E. Chaney, D. K. Patel, R. E. Elmquist, M. C. Hersam, J. Mater. Chem. C 2020, 8, 15086.
[29]. S. A. Wells, A. Henning, J. T. Gish, V. K. Sangwan, L. J. Lauhon, M. C. Hersam, Nano Lett. 2018, 18, 7876.
[30]. J. Li, M. M. Naiini, S. Vaziri, M. C. Lemme, M. Östling, Adv. Funct. Mater. 2014, 24, 6524.
[31]. D. McManus, S. Vranic, F. Withers, V. Sanchez-Romaguera, M. Macucci, H. Yang, R. Sorrentino, K. Parvez, S. K. Son, G. Iannaccone, K. Kostarelos, G. Fiori, C. Casiraghi, Nat. Nanotechnol. 2017, 12, 343.
[32]. F. I. Alzakia, W. Jonhson, J. Ding, S. C. Tan, ACS Appl. Mater. Interfaces 2020, 12, 28840.
[33]. S. Zhang, L. Cai, T. Wang, J. Miao, N. Sepúlveda, C. Wang, Appl. Phys. Lett. 2017, 110, 123105.
[34]. G. Azzellino, A. Grimoldi, M. Binda, M. Caironi, D. Natali, M. Sampietro, Adv. Mater. 2013, 25, 6829.
[35]. S. Tong, C. Gong, C. Zhang, G. Liu, D. Zhang, C. Zhou, J. Sun, S. Xiao, J. He, Y. Gao, J. Yang, Appl. Mater. Today 2019, 15, 389.
[36]. A. M. Alamri, S. Leung, M. Vaseem, A. Shamim, J. H. He, IEEE Trans. Electron Devices 2019, 66, 2657.
[37]. Y. Li, X. Feng, M. Sivan, J. F. Leong, B. Tang, X. Wang, J. N. Tey, J. Wei, K. W. Ang, A. V. Y. Thean, IEEE Sens. J. 2020, 20, 4653.
[38]. J. T. Seo, J. Zhu, V. K. Sangwan, E. B. Secor, S. G. Wallace, M. C. Hersam, ACS Appl. Mater. Interfaces 2019, 11, 5675.
[39]. J. Kim, D. Rhee, O. Song, M. Kim, Y. Kwon, D. Lim, I. Kim, v. Mazanek, L. Valdman, Z. Sofer, J. Cho, J. Kang, Advanced Materials 2021, 34, 2106110.
[40]. P. Turner, M. Hodnett, R. Dorey, J. D. Carey, Scientific Reports 2019, 9, 8710.
[41]. M. Telkhozhayeva, E. Teblum, R. Konar, O. Girshevitz, I. Perelshtein, H. Aviv, Y. R. Tischler, G. D. Nessim, Langmuir 2021, 37, 4505.
[42]. J. Kang, J. T. Seo, D. Alducin, A. Ponce, M. J. Yacaman, M. C. Hersam, Nature Comm. 2014, 5, 5478.
[43]. C. Backes, B. M. Szydlowska, A. Harvey, S. Yuan, V. Vega-Mayora, B. R. Davies, P. Zhao, D. Hanlon, E. J. G. Santos, M. I. Katsnelson, W. J. Blau, C. Gadermaier, J. N. Coleman, ACS Nano 2016, 10, 1589-1601.
[44]. K. Parate, S. V. Rangnekar, D. Jing, D. L. Mendivelso-Perez, S. Ding, E. B. Secor, E. A. Smith, J. M. Hostetter, M. C. Hersam, J. C. Claussen, ACS Appl. Mater. Interfaces 2020, 12, 8592.
[45]. E. B. Secor, B. Y. Ahn, T. Z. Gao, J. A. Lewis, M. C. Hersam, 2015, Advanced Materials, 27, 6683.
[46]. M. C. Hersam, J. T. Seo, J. Zhu, US PG Patent Application Publication No. US20210398808A1, Dec. 23, 2021.

1. A nanomaterial ink, comprising:
at least one solvent; and
at least one two-dimensional (2D) semiconductor dispersed in the at least one solvent.

2. The nanomaterial ink of claim 1, further comprising at least one ink additive that affects at least one ink property including substrate wetting, rheology, particle aggregation, particle stability, phase stability, UV stability, fluorescence, ink drying dynamics, electrical properties, pH stability, foaming, and oxidation.

3. The nanomaterial ink of claim 2, wherein the at least one ink additive comprises
surfactants including sodium cholate, sodium dodecylsulfate, and/or cetyl trimethylammonium bromide; and/or
polymers including polyvinylpyrrolidone, ethyl cellulose, nitrocellulose, nanocellulose, and/or poloxamers.

4. The nanomaterial ink of claim 1, wherein the at least one solvent comprises
water;
low boiling point alcohols including ethanol, isopropyl alcohol, and/or 2-butanol;
polar aprotic solvents including acetone, acetonitrile, N-methyl pyrrolidone, dimethylformamide, N-cyclohexyl-2-pyrrolidone, propylene carbonate, dimethyl sulfoxide, tetrahydrofuran, and/or dihydrolevoglucosenone;
high boiling point organic solvents including ethylene glycol, terpineol, and/or dibutyl phthalate; and/or
other organic solvents including toluene, xylene, ethyl lactate, and/or cyclohexanone.

5. The nanomaterial ink of claim 1, wherein the at least one 2D semiconductor comprises nanoparticles including nanosheets, nanoflakes, nanofibers, nanotubes, or combinations of them.

6. The nanomaterial ink of claim 5, wherein the at least one 2D semiconductor comprises
elemental semiconductors including phosphorene, germanene, tellurine, selenine, and/or stanine;
monochalcogenides including GeS, InSe, GaTe, PbTe, SnS, and/or SnSe;
dichalcogenides including MoS₂, WSe₂, TaS₂, ReS₂, and/or MoTe₂;
trichalcogenides including NbSe₃, GaInS₃, Bi₂Se₃, and/or In₂Se₃;
2D semiconducting oxides including MnO₃ and/or V₂O₅; and/or
semiconducting MXenes including Mn₂CO₂, Ti₂C, Sc₂CF₂, and/or Cr₂CF₂.

7. The nanomaterial ink of claim 1, wherein the at least one 2D semiconductor is obtained by electrochemical intercalation, and exfoliation.

8. The nanomaterial ink of claim 7, wherein the exfoliation comprises megasonic exfoliation.

9. The nanomaterial ink of claim 8, wherein the at least one 2D semiconductor has thicknesses at a single-nanometer scale and lateral sizes at a micron-scale.

10. The nanomaterial ink of claim 9, wherein the at least one 2D semiconductor has the thicknesses of less than about 2 nm, and the lateral sizes of about 0.5-3 μm.

11. The nanomaterial ink of claim 1, being applicable for drop casting, spin coating, dip coating, spray coating, blade coating, inkjet printing, aerosol jet printing, gravure printing, screen printing, electrodynamic jet printing, direct ink writing, 3D printing, microcontact printing, Langmuir-Blodgett assembly, layer-by-layer assembly, field-directed assembly, vacuum filtration assembly, and/or confined assembly.

12. The nanomaterial ink of claim 1, being formed such that a film is formable to have percolating networks by a single printing pass, or multiple printing passes of the 2D nanomaterial ink.

13. A method of forming a nanomaterial ink, comprising:
providing at least one 2D semiconductor; and
dispersing the at least one 2D semiconductor in at least one solvent to form the nanomaterial ink.

14. The method of claim 13, wherein the at least one solvent comprises
water;
low boiling point alcohols including ethanol, isopropyl alcohol, and/or 2-butanol;
polar aprotic solvents including acetone, acetonitrile, N-methyl pyrrolidone, dimethylformamide, N-cyclohexyl-2-pyrrolidone, propylene carbonate, dimethyl sulfoxide, tetrahydrofuran, and/or dihydrolevoglucosenone;
high boiling point organic solvents including ethylene glycol, terpineol, and/or dibutyl phthalate; and/or
other organic solvents including toluene, xylene, ethyl lactate, and/or cyclohexanone.

15. The method of claim 13, wherein said providing the at least one 2D semiconductor comprises:
electrochemically intercalating a bulk single crystal semiconductor to obtain an intercalated crystal semiconductor; and
pre-exfoliating the intercalated crystal semiconductor using bath sonication to obtain the at least one 2D semiconductor.

16. The method of claim 13, wherein the at least one 2D semiconductor comprises nanoparticles comprising nanosheets, nanoflakes, nanofibers, nanotubes, or combinations of them.

17. The method of claim 16, wherein the at least one 2D semiconductor comprises
elemental semiconductors including phosphorene, germanene, tellurine, selenine, and/or stanine;
monochalcogenides including GeS, InSe, GaTe, PbTe, SnS, and/or SnSe;
dichalcogenides including MoS₂, WSe₂, TaS₂, ReS₂, and/or MoTe₂;
trichalcogenides including NbSe₃, GaInS₃, Bi₂Se₃, and/or In₂Se₃;
2D semiconducting oxides including MnO₃ and/or V₂O₅; and/or
semiconducting MXenes including Mn₂CO₂, Ti₂C, Sc₂CF₂, and/or Cr₂CF₂.

18. The method of claim 13, further comprising megasonically exfoliating the nanomaterial ink.

19. The method of claim 18, wherein the at least one 2D semiconductor has thicknesses at a single-nanometer scale and lateral sizes at a micron-scale.

20. The method of claim 19, wherein the at least one 2D semiconductor has the thicknesses of less than about 2 nm, and the lateral sizes of about 0.5-3 μm.

21. The method of claim 18, wherein said megasonic exfoliation of the nanomaterial ink is performed in a container containing one or several piezoelectric transducers.

22. The method of claim 18, wherein said megasonic exfoliation of the nanomaterial ink is performed in a container containing a single piezoelectric transducer with a resonant frequency larger than 350 kHz, preferably 950 kHz or 1.65 MHz.

23. The method of claim 18, wherein said megasonic exfoliation of the nanomaterial ink is performed in a container containing an array of piezoelectric transducers, each with an independent resonant frequency larger than 350 kHz, preferably 950 kHz or 1.65 MHz.

24. The method of claim 18, wherein said megasonic exfoliation of the nanomaterial ink is performed in a container containing one or several piezoelectric transducers, and the ink is placed directly into the container for exposure to the megasonic acoustic energy.

25. The method of claim 18, wherein said megasonic exfoliation of the nanomaterial ink is performed in a container containing one or several piezoelectric transducers and an acoustic medium including water.

26. The method of claim 18, wherein said megasonic exfoliation of the nanomaterial ink is performed in a container containing one or several piezoelectric transducers and an acoustic medium including water, in which the nanomaterial ink is placed in a secondary container that is submerged in the acoustic medium and is designed to transmit megasonic frequency.

27. The method of claim 18, wherein said megasonic exfoliation of the nanomaterial ink is performed in a megasonic container including one or several piezoelectric transducers and an acoustic medium including water, in which the nanomaterial ink is placed in a thin-walled plastic container that is held at the surface of the acoustic medium or is submerged in the acoustic medium.

28. The method of claim 18, wherein said megasonic exfoliation of the nanomaterial ink is performed in a megasonic container including one or several piezoelectric transducers and an acoustic medium including water, in which the nanomaterial ink is placed in a thin-walled plastic container that may or may not be permeable to air.

29. The method of claim 18, wherein said megasonic exfoliation of the nanomaterial ink is performed using an aerosol jet printer (AJP) outfitted with an ultrasonic atomizer that operates at a frequency greater than 350 kHz, preferably 950 kHz or 1.65 MHz.

30. A device, comprising:
at least one element formed of the nanomaterial ink according to claim 1 on a substrate.

31. The device of claim 30, wherein the substrate comprises a rigid substrate or a flexible substrate.

32. The device of claim 30, wherein the at least one element is thermally annealed or photonically annealed.

33. The device of claim 30, further comprising electrodes coupled with the at least one element.

34. The device of claim 33, wherein the electrodes are formed by gas phase deposition of a metal or a stack of metals including gold, chromium, indium, nickel, and titanium.

35. The device of claim 33, wherein the electrodes are formed by growth of a conductive material including graphene, MoO₃, and NbS₂.

36. The device of claim 33, wherein the electrodes are formed by depositing a conductive ink comprising at least one active material including
metal nanoparticles or metal complexes including gold, silver, copper, nickel, palladium, and/or platinum;
liquid metals including eGaIn;
carbon nanomaterials including carbon nanotubes, graphene, fullerenes, graphene oxide, and/or reduced graphene oxide;
conductive polymers including poly(3,4-ethylenedioxythiophene) polystyrene sulfonate (PEDOT:PSS), polyaniline (PANI), polypyrrole (PPy), polyacetylene, and/or polythiophene (PT); and/or
conductive 2D materials including IT-MoS₂, NbS2, and/or Ti3C2Tx MXenes.

37. The device of claim 30, wherein the device comprises an electronic device including a transistor, a memristor, a diode, a power converter, a sensor, a battery, a resistor, integrated circuit elements, or combinations of them.

38. The device of claim 30, wherein the device comprises an optoelectronic device including a photodetector, a photosensor, a photodiode, a solar cell, a phototransistor, a light-emitting diode, a laser diode, integrated optical circuit (IOC) elements, a photoresistor, a charge-coupled imaging device, or combinations of them.

39. The device of claim 30, wherein the at least one element is formed by aerosol jet printing (AJP), during which megasonic atomization induces exfoliation and yields a high fraction of monolayer nanosheets of the at least one 2D semiconductor.

40. The device of claim 38, wherein the optoelectronic device has responsivities exceeding 10³ A/W that outperforms previously reported all-printed visible photodetectors by over 3 orders of magnitude.

41. A method of forming a device, comprising:
forming at least one element on a substrate with the nanomaterial ink according to claim 1; and
annealing the at least one element to decompose the solvent and enhance electrical contact between nanoparticles of the at least one 2D semiconductor in the at least one element.

42. The method of claim 41, further comprising forming electrodes with a graphene ink, wherein the electrodes are coupled with the at least one element.

43. The method of claim 41, wherein said forming the at least one element is performed with aerosol jet printing (AJP), during which megasonic atomization induces exfoliation and yields a high fraction of monolayer nanosheets of the at least one 2D semiconductor.

44. The method of claim 41, wherein said annealing the at least one element is performed with thermal annealing or photonic annealing.
